(19) United States
(12) Patent Application Publication
(10) Pub. No.: US 2026/0304752 A1
(43) Pub. Date: Oct. 1, 2026

(54) SEMICONDUCTOR DEVICES AND FABRICATING METHODS THEREOF

(71) Applicant: Yangtze Memory Technologies Holding Co., Ltd., Wuhan (CN)

(72) Inventors: Changzhi SUN, Wuhan (CN); Di Wang, Wuhan (CN); Wenxi Zhou, Wuhan (CN); Zhiliang Xia, Wuhan (CN)

(21) Appl. No.: 19/236,810

(22) Filed: Jun. 12, 2025

Related U.S. Application Data
(63) Continuation of application No. PCT/CN2025/085005, filed on Mar. 26, 2025.

(51) Int. Cl. H10B 12/00; H10D 1/68; H10D 30/63; H10D 62/17

(52) U.S. Cl. CPC H10B 12/33; H10B 12/05; H10B 12/482; H10B 12/485; H10D 1/716; H10D 30/63; H10D 62/292

(57) ABSTRACT

A semiconductor device includes an insulating wall, a first gate electrode layer, a second gate electrode layer, a first semiconductor layer, and a second semiconductor layer. The insulating wall has a first side and a second side opposite each. The first gate electrode layer and the second gate electrode layer extend along the first direction and are coupled to the first side and the second side of the insulating wall respectively. The first semiconductor layer and the second semiconductor layer extend along the first direction and are coupled to the first gate electrode layer and the second gate electrode layer respectively. A first end of the first semiconductor layer and a first end of the second semiconductor layer are connected. The first gate electrode layer and the second gate electrode layer are disposed between the first semiconductor layer and the second semiconductor layer in the third direction.

### CROSS-REFERENCE TO RELATED APPLICATIONS

This application is a continuation of International Application No. PCT/CN2025/085005, filed on Mar. 26, 2025, which is hereby incorporated by reference in its entirety.

### TECHNICAL FIELD

The present disclosure generally relates to the field of semiconductor technology and, more particularly, to semiconductor devices and fabricating methods thereof.

### BACKGROUND

Planar memory cells are scaled to smaller sizes by improving process technology, circuit design, programming algorithm, and fabrication process. However, as feature sizes of the memory cells approach a lower limit, the planar process and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuit structures to facilitate the operations of the memory array.

### SUMMARY

Some aspects of the present disclosure provide a semiconductor device including a gate dielectric layer, a gate electrode layer, and a semiconductor layer. The gate dielectric layer extends in a plane along a first direction and a second direction perpendicular to the first direction. The gate electrode layer is coupled to a first side of the gate dielectric layer in a third direction perpendicular to the first and second directions. The semiconductor layer includes a first portion and a second portion. The first portion extends along the first direction and overlaps with the gate electrode layer in the first direction. The second portion is in contact with a second side of the gate dielectric layer opposite to the first side in the third direction and overlaps with the gate electrode layer in the third direction.

In some implementations, the semiconductor layer further includes a third portion connected between the first portion and the second portion and extends at least along a fourth direction different from the first and second directions.

In some implementations, the third portion is stepped-shaped.

In some implementations, a length of the second portion in the first direction is equal to or greater than a length of the gate electrode layer in the first direction.

In some implementations, the semiconductor layer further includes a fourth portion in contact with an end of the second portion away from the first portion and extending along the third direction. The fourth portion is located at the second side of the gate dielectric layer and extends away from the gate electrode layer.

In some implementations, the fourth portion is coupled with a bit line.

In some implementations, the semiconductor layer further includes a fifth portion in contact with an end of the first portion away from the second portion and extending along the third direction. The fifth portion of the semiconductor layer is in contact with a fifth portion of an adjacent semiconductor layer.

In some implementations, the fifth portion is coupled with a storage unit.

In some implementations, the semiconductor device further includes an insulating wall located adjacent to the second side of the gate dielectric layer in the third direction.

In some implementations, a length of the gate dielectric layer in the first direction is equal to a length of the gate electrode layer in the first direction.

In some implementations, a length of the gate dielectric layer in the first direction is equal to a length of the semiconductor layer in the first direction.

In some implementations, a leakage value of the semiconductor layer is lower than a pico-ampere.

In some implementations, the semiconductor layer includes one or a combination of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O.

In some implementations, the gate electrode layer comprises a first sub-layer extending along the first direction and a second sub-layer connected to an end of the first sub-layer and extending along the third direction.

In some implementations, the second sub-layer of the gate electrode layer is located between the first sub-layer of the gate electrode layer and the semiconductor layer.

Some aspects of the present disclosure provide a semiconductor device including an insulating wall, a first gate electrode layer, a second gate electrode layer, a first semiconductor layer, and a second semiconductor layer. The insulating wall extends along a first direction and a second direction perpendicular to the first direction. The insulating wall has a first side and a second side opposite each other in a third direction perpendicular to the first direction and second direction. The first gate electrode layer and the second gate electrode layer extend along the first direction and are coupled to the first side and the second side of the insulating wall respectively. The first semiconductor layer and the second semiconductor layer extend along the first direction and are coupled to the first gate electrode layer and the second gate electrode layer respectively. A first end of the first semiconductor layer away from the substrate and a first end of second semiconductor layer away from the substrate are connected. The first gate electrode layer and the second gate electrode layer are disposed between the first semiconductor layer and the second semiconductor layer in the third direction.

In some implementations, the first semiconductor layer includes a first section extending along the first direction and overlapping with the first gate electrode layer in the first direction and a second section extending along the first direction and overlapping with the first gate electrode layer in the third direction.

In some implementations, the first semiconductor layer further includes a third section connected between the first section and the second section and extends at least along a fourth direction different from the first and second directions. In some implementations, the third section is stepped-shaped.

In some implementations, a length of the second section in the first direction is equal to or greater than a length of the first gate electrode layer in the first direction.

In some implementations, the second semiconductor layer further includes a fourth section extending along the first direction and overlapping with the second gate electrode layer in the first direction and a fifth section extending along the first direction and overlapping with the second gate electrode layer in the third direction.

In some implementations, the second semiconductor layer further includes a sixth section connected between the fourth section and the fifth section and extending at least along a fourth direction different from the first and second directions.

In some implementations, the sixth section is stepped-shaped.

In some implementations, a length of the fifth section in the first direction is equal to or greater than a length of the second gate electrode layer in the first direction.

In some implementations, the first semiconductor layer further includes a seventh section in contact with an end of the second section away from the first section and extending along the third direction. The seventh section extends away from the first gate electrode layer.

In some implementations, the second semiconductor layer further includes an eighth section in contact with an end of the fifth section away from the first section and extending along the third direction. The eighth section extends away from the second gate electrode layer.

In some implementations, the first semiconductor layer further includes a ninth section in contact with an end of the first section away from the second section and extending toward the second semiconductor layer along the third direction. The ninth section is in contact with the second semiconductor layer.

In some implementations, the second semiconductor layer further includes a tenth section in contact with an end of the fourth section away from the fifth section and extending toward the first semiconductor layer along the third direction. The tenth section is in contact with the first semiconductor layer.

In some implementations, the ninth section and the tenth section are in contact with a bit line.

In some implementations, a first distance between a first end of the first semiconductor layer and a first end of the second semiconductor layer is smaller than a second distance between a second end of the first semiconductor layer and a second end of the second semiconductor layer. The first end of the first semiconductor layer is coupled to a first bit line. The first end of the second semiconductor layer is coupled to the first bit line. The second end of the first semiconductor layer is coupled to a first storage unit. The second end of the second semiconductor layer is coupled to a second storage unit.

In some implementations, the first gate electrode layer includes a first sub-layer extending along the first direction and a second sub-layer connected to an end of the first sub-layer and extending along the third direction.

In some implementations, the second sub-layer of the first gate electrode layer is located between the first sub-layer of the first gate electrode layer and the first semiconductor layer.

In some implementations, the second gate electrode layer includes a third sub-layer extending along the first direction and a fourth sub-layer connected to an end of the third sub-layer and extending along the third direction.

In some implementations, the second sub-layer of the second gate electrode layer is located between the third sub-layer of the second gate electrode layer and the second semiconductor layer.

In some implementations, a leakage value of the first semiconductor layer and the second semiconductor layer is lower than a pico-ampere.

In some implementations, the first semiconductor layer and the second semiconductor layer include one or a combination of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O.

Some aspects of the present disclosure provide a semiconductor device including an insulating wall, a first gate electrode layer, a second gate electrode layer, a first semiconductor layer, and a second semiconductor layer. The insulating wall is formed on a substrate and extends along a first direction and a second direction perpendicular to the first direction. The insulating wall has a first side and a second side opposite each other in a third direction perpendicular to the first direction and second direction. The first gate electrode layer and the second gate electrode layer extend along the first direction and are coupled to the first side and the second side of the insulating wall respectively. The first semiconductor layer and the second semiconductor layer extend along the first direction and are coupled to the first gate electrode layer and the second gate electrode layer, respectively. A first distance between a first end of the first semiconductor layer and a first end of the second semiconductor layer is smaller than a second distance between a second end of the first semiconductor layer and a second end of the second semiconductor layer. The first end of the first semiconductor layer is coupled to a first bit line. The first end of the second semiconductor layer is coupled to the first bit line. The second end of the first semiconductor layer is coupled to a first storage unit. The second end of the second semiconductor layer is coupled to a second storage unit.

In some implementations, the first semiconductor layer includes a first section extending along the first direction and overlapping with the first gate electrode layer in the first direction and a second section extending along the first direction and overlapping with the first gate electrode layer in the third direction.

In some implementations, the first semiconductor layer further includes a third section connected between the first section and the second section and extends at least along a fourth direction different from the first and second directions.

In some implementations, the third section is stepped-shaped.

In some implementations, a length of the second section in the first direction is equal to or greater than a length of the first gate electrode layer in the first direction.

In some implementations, the second semiconductor layer further includes a fourth section extending along the first direction and overlapping with the second gate electrode layer in the first direction and a fifth section extending along the first direction and overlapping with the second gate electrode layer in the third direction.

In some implementations, the second semiconductor layer further includes a sixth section connected between the fourth section and the fifth section and extends at least along a fourth direction different from the first and second directions.

In some implementations, the sixth section is stepped-shaped.

In some implementations, a length of the fifth section in the first direction is equal to or greater than a length of the second gate electrode layer in the first direction.

In some implementations, the first semiconductor layer further includes a seventh section in contact with an end of the second section away from the first section and extending along the third direction. The seventh section extends away from the first gate electrode layer.

In some implementations, the second semiconductor layer further includes an eighth section in contact with an end of the fifth section away from the first section and extending along the third direction. The eighth section extends away from the second gate electrode layer.

In some implementations, the first semiconductor layer further includes a ninth section in contact with an end of the first section away from the second section and extending toward the second semiconductor layer along the third direction. The ninth section is in contact with the second semiconductor layer.

In some implementations, the second semiconductor layer further includes a tenth section in contact with an end of the fourth section away from the fifth section and extending toward the first semiconductor layer along the third direction. The tenth section is in contact with the first semiconductor layer.

In some implementations, the ninth section and the tenth section are in contact with a bit line.

Some aspects of the present disclosure provide a method of fabricating a semiconductor device. The method includes: forming an insulating wall extending along a first direction and a second direction perpendicular to the first direction, the insulating wall having a first side and a second side opposite to each other in a third direction perpendicular to the first direction and second direction; forming a first gate electrode layer and a second gate electrode layer extending along the first direction and coupled to the first side and the second side of the insulating wall respectively; forming a first semiconductor layer and a second semiconductor layer extending along the first direction and coupled to the first gate electrode layer and the second gate electrode layer respectively. The first gate electrode layer and the second gate electrode layer are disposed between the first semiconductor layer and the second semiconductor layer in the third direction.

In some implementations, the method further includes forming a bottom dielectric layer under the insulating wall and extending along the second direction and the third direction. A material of the bottom dielectric layer is different with a material of the insulating wall.

In some implementations, forming the first gate electrode layer and the second gate electrode layer includes forming a conductive layer covering the insulating wall and patterning the conductive layer to form the first gate electrode layer coupled to the first side of the insulating wall in the third direction and the second gate electrode layer coupled to the second side of the insulating wall in the third direction.

In some implementations, forming the first gate electrode layer and the second gate electrode layer further includes patterning the bottom dielectric layer to remove part of the bottom dielectric layer that is exposed from the first gate electrode layer, the second gate electrode layer, and the insulating wall.

In some implementations, forming the first semiconductor layer and the second semiconductor layer further includes forming a gate dielectric layer covering the first gate electrode layer and the second gate electrode layer in the third direction and covering an end of the insulating wall in the first direction; forming an intermediate semiconductor layer covering the gate dielectric layer; and patterning the intermediate semiconductor layer to form the first semiconductor layer and the second semiconductor layer.

In some implementations, a first distance between a first end of the first semiconductor layer and a first end of the second semiconductor layer is smaller than a second distance between a second end of the first semiconductor layer and a second end of the second semiconductor layer. The first end of the first semiconductor layer and the first end of the second semiconductor layer are away from the substrate. The second end of the first semiconductor layer and the second end of the second semiconductor layer are close to the substrate.

In some implementations, a leakage value of the first semiconductor layer and the second semiconductor layer is lower than a pico-ampere.

In some implementations, the first semiconductor layer and the second semiconductor layer include one or a combination of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a schematic circuit diagram of a semiconductor device including an array of memory cells according to some implementations of the present disclosure.

FIG. 2 illustrates a perspective view of a semiconductor device according to some implementations of the present disclosure.

FIG. 3A illustrates a perspective view of a semiconductor device according to some implementations of the present disclosure.

FIG. 3B illustrates a cross-sectional view of the semiconductor device along the y-direction according to some implementations of the present disclosure.

FIG. 3C is a partially enlarged view of region A in FIG. 3B, according to some implementations of the present disclosure.

FIG. 3D is a partially enlarged view of region A in FIG. 3B, according to some implementations of the present disclosure.

FIG. 3E is a partially enlarged view of region B in FIG. 3B, according to some implementations of the present disclosure.

FIG. 3F is a partially enlarged view of region B in FIG. 3B, according to some implementations of the present disclosure.

FIG. 4 illustrates a flowchart of a fabricating method for forming a semiconductor device, according to some implementations of the present disclosure.

FIGS. 5A-5H illustrates a schematic view of the semiconductor device at a certain fabricating stage of the method shown in FIG. 4, according to various implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. The present disclosure can also be used in a variety of other applications. Functional and structural features, as described in the present disclosures, can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for the existence of additional factors not necessarily expressly described, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature’s relationship to another element(s) or feature(s) as illustrated in the figures. The spatially relative terms are intended to encompass different orientations of the device in use or operation and the orientation depicted in the figures. The apparatus may be otherwise oriented (rotated 90 degrees or at other orientations), and the spatially relative descriptors used herein may be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Metal oxide semiconductor materials, such as IGZO, exhibit high electron mobility, enabling faster switching speeds compared to traditional silicon-based materials. This results in improved read/write speeds and reduced power consumption in memory devices. Additionally, these materials possess excellent optical properties, making them suitable for transparent displays and broadening their application potential. However, the performance of metal oxide semiconductor materials is highly temperature-sensitive. Elevated temperatures can induce phase transitions, disrupting their lattice structure and significantly degrading their performance. This poses a significant challenge in memory device fabrication, where high-temperature processes such as oxidation, deposition, annealing, and diffusion—often exceeding 1000°C—are essential.

In conventional manufacturing processes, the gate structure is typically formed after the fabrication of the metal oxide semiconductor layer. The formation of the gate structure involves multiple high-temperature steps, including oxidation, photolithography, deposition, annealing, and etching, which are incompatible with the thermal limitations of metal oxide semiconductor materials. Therefore, low-temperature alternatives, such as low-temperature chemical vapor deposition (LT-CVD) or RF sputtering and low-temperature annealing (150°C–300°C), have been employed to address these problems. While these alternatives mitigate the thermal impact on metal oxide semiconductor materials, they often compromise performance. For instance, low-temperature annealing may inadequately address defects, improve crystal structure, or relieve internal stress, leading to suboptimal electrical properties. Furthermore, the increased cost and extended process cycles associated with low-temperature equipment elevate manufacturing complexity and expenses.

To address one or more of the aforementioned issues, the present disclosure introduces a fabricating method for semiconductor devices incorporating metal oxide semiconductor materials. In this method, the gate structure of each semiconductor device is formed prior to the metal oxide semiconductor layer, thereby eliminating the thermal impact of gate fabrication on the metal oxide semiconductor material. This approach also removes the thermal budget constraints imposed by the metal oxide semiconductor materials, allowing the unrestricted use of high-temperature processes for gate formation. As a result, the present disclosure significantly enhances the manufacturability and performance of memory devices utilizing metal oxide semiconductors.

Consistent with the scope of the present disclosure, according to some implementations of the present disclosure, a semiconductor device corresponding to the fabricating method is provided. The semiconductor layer of the semiconductor device includes a first portion, a second portion, and a third portion. The first portion extends along a first direction and overlaps with a gate electrode layer in the first direction. The second portion is in contact with a second side of the gate dielectric layer opposite to the first side in the third direction and overlaps with the gate electrode layer in the third direction. The third portion is connected between the first portion and the second portion and extends at least along a fourth direction different from the first and second directions.

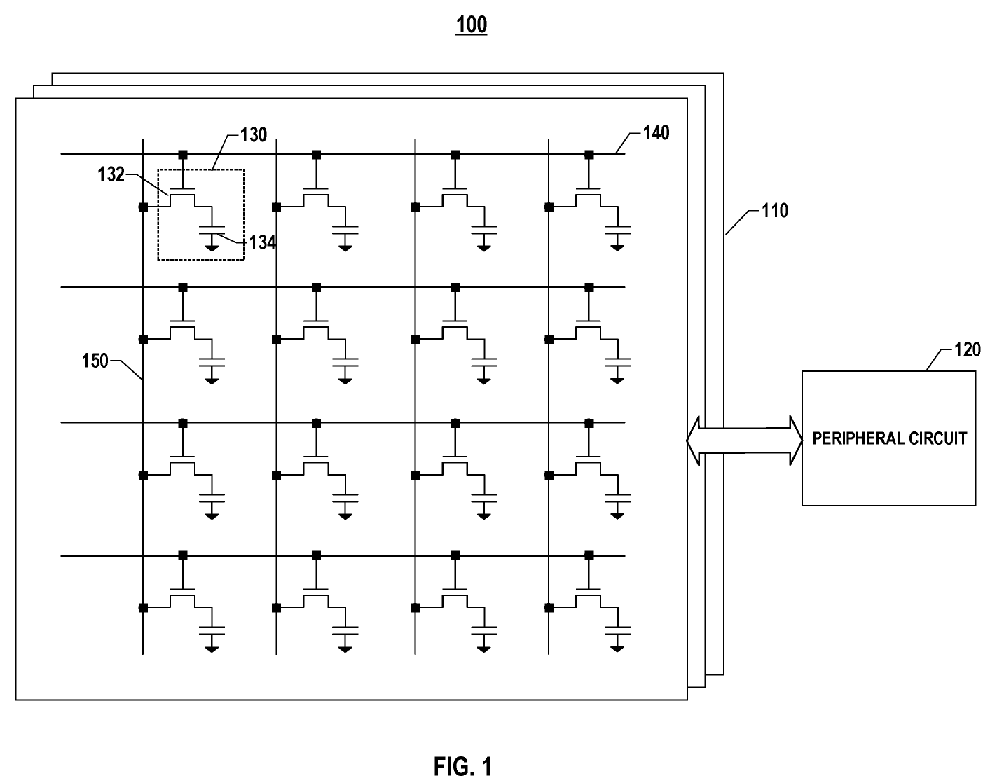

FIG. 1 illustrates a schematic diagram of a memory device 100 including peripheral circuits and an array of memory cells. Each memory cell has a vertical transistor, according to some aspects of the present disclosure. Memory device 100 can include a memory cell array 110 and peripheral circuits 120 coupled to memory cell array 110. Memory cell array 110 can be any suitable memory cell array in which each memory cell 130 includes a vertical transistor 132 and a storage unit 134 coupled to vertical transistor 132. In some implementations, memory cell array 110 is a DRAM cell array, and storage unit 134 is a capacitor for storing charge as the binary information stored by the respective DRAM cell.

As shown in FIG. 1, memory cells 130 can be arranged in a two-dimensional (2D) array having rows and columns. Memory device 100 can include word lines 140 coupling peripheral circuits 120 and memory cell array 110 for controlling the switch of vertical transistors 132 in memory cells 130 located in a row, as well as bit lines 150 coupling peripheral circuits 120 and memory cell array 110 for sending data to and/or receiving data from memory cells 130 located in a column. That is, each word line 140 is coupled to a respective row of memory cells 130, and each bit line is coupled to a respective column of memory cells 130. Consistent with the scope of the present disclosure, vertical transistors 132, such as vertical metal-oxide-semiconductor field-effect transistors (MOSFETs), can replace the conventional planar transistors as the pass transistors of memory cells 130 to reduce the area occupied by the pass transistors, the coupling capacitance, as well as the interconnect routing complexity, as described below in detail.

In some embodiments, each memory cell 130 includes a storage unit 134 for storing a bit of data as a positive or negative electrical charge as well as one or more transistors (a.k.a. pass transistors) that control (e.g., switch and selecting) access to it. In some implementations, each memory cell is a one-transistor, one-capacitor (1T1C) cell. Since transistors always leak a small amount of charge, the capacitors will slowly discharge, causing information stored in them to drain. As such, a memory cell has to be refreshed to retain data, for example, by the peripheral circuit structure 120 coupled to the memory cell array 110, according to some implementations. In some implementations, storage unit 134 can be pillar capacitors, which are formed after forming the vertical transistors 132. Both the outer and inner surfaces of a pillar capacitor can be utilized as effective capacitor areas. This structure can be utilized to achieve greater packing density in a semiconductor device. In some other implementations, storage unit 134 can be cup capacitors, which are formed before forming the vertical transistors 132. In such implementations, the high-temperature processes of forming the cup capacitors do not affect the formation of vertical transistors 132. Thus, metal oxide semiconductors can be employed as the channel structures of vertical transistors 132.

Peripheral circuit structures 120 can include any suitable digital, analog, and/or mixed-signal circuits used for facilitating the operations of the memory cell array. For example, the peripheral circuit structure can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuit structures 120 use complementary metal-oxide-semiconductor (CMOS) technology, e.g., which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations. Memory device 100 can include word lines 140 coupling peripheral circuit structures 120 and memory cell array 110 for controlling the switch of vertical transistors 132 in memory cells 130 located in a row, as well as bit lines 150 coupling peripheral circuit structures 120 and memory cell array 110 for sending data to and/or receiving data from memory cells 130 located in a column. That is, each word line 140 is coupled to a respective row of memory cells 130, and each bit line 150 is coupled to a respective column of memory cells 130.

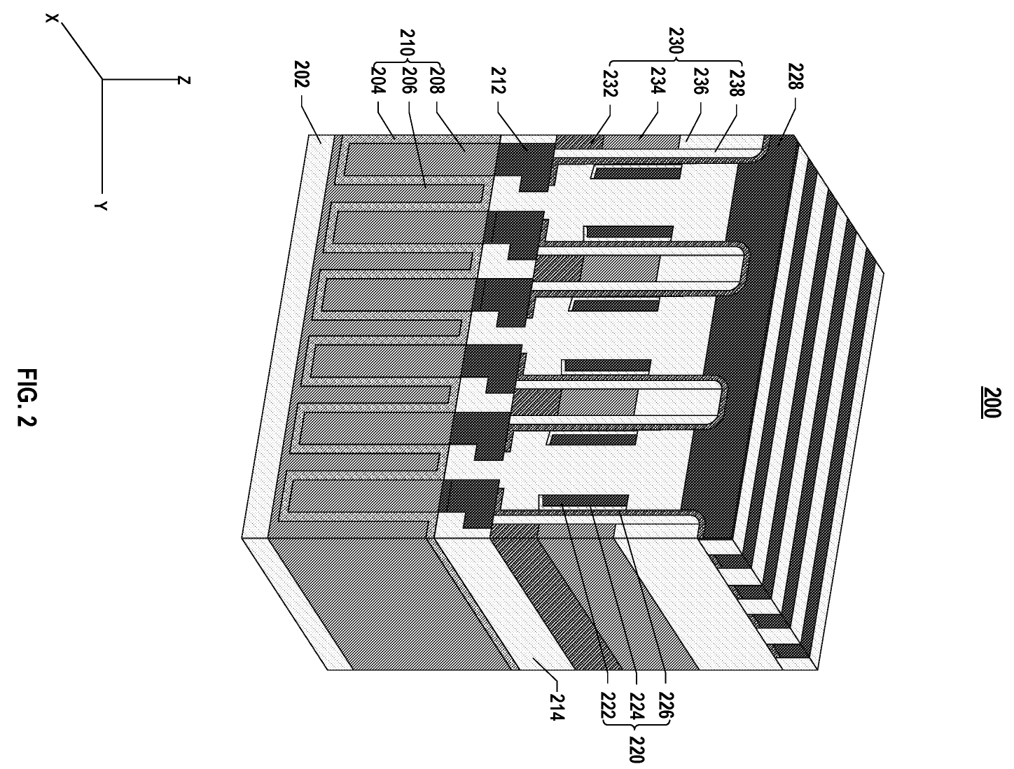

FIG. 2 illustrates a perspective view of a semiconductor device 200 according to some implementations of the present disclosure. Semiconductor device 200 can be a DRAM device in which memory cells are provided in the form of an array of DRAM cells. In some embodiments, each DRAM cell includes a capacitor 210 for storing a bit of data as a positive or negative electrical charge as well as one or more vertical transistors 220 (a.k.a. pass transistors) that control (e.g., switch and selecting) access to it. In some implementations, each DRAM cell is a one-transistor, one-capacitor (1T1C) cell. Since transistors always leak a small amount of charge, the capacitors will slowly discharge, causing information stored in them to drain. As such, a DRAM cell has to be refreshed to retain data according to some implementations. It is understood that the DRAM cells may be of any suitable configurations, such as 2T1C cell, 3T1C cell, etc.

Vertical transistor 220 can be a MOSFET used to switch a respective DRAM cell. In some implementations, vertical transistor 220 includes a semiconductor layer 226 (i.e., the active region in which multiple channels can form) extending vertically (in the z-direction) and a gate structure coupled with a plurality of sides of semiconductor layer 226.

In some implementations, the semiconductor layer 226 exhibits a leakage value of less than a pico-ampere. For example, the semiconductor layer 226 may include a metal oxide semiconductor material. The conduction band orbitals of metal oxide semiconductor materials typically overlap, resulting in carrier mobility that is less dependent on the degree of ordering in the thin film material. As a result, metal oxide semiconductors exhibit a mobility range of approximately 1 to 100 cm²·V⁻¹·s⁻¹, significantly higher than that of silicon. This property contributes to superior electrical uniformity compared to silicon. Additionally, metal oxide semiconductors are compatible with low-temperature processing, making them suitable for integration with amorphous silicon (a-Si) thin-film transistor (TFT) processes. This compatibility enables fabrication on flexible plastic substrates and facilitates low-cost manufacturing, as ion implantation and crystallization equipment are not required.

In a vertical structure, metal oxide semiconductor materials offer unique advantages, including the ability to achieve short channel lengths, reduce device footprint, and mitigate mechanical stress in flexible substrates. Even when cracks form in the channel layer due to compressive or tensile strain, carriers can still transport efficiently in the vertical direction. These characteristics make metal oxide semiconductors particularly promising for flexible electronics applications. In some implementations, semiconductor layer 226 can be one or more of indium gallium zinc oxide (InₓGa_{y}Zn_{z}O), indium gallium silicon oxide (InₓGa_{y}Si_{z}O), indium stannum zinc oxide (InₓSn_{y}Zn_{z}O), indium zinc oxide (InₓZn_{y}O), zinc oxide (ZnₓO), zinc stannum oxide (ZnₓSn_{y}O), zinc oxide nitride (ZnₓO_{y}N), zirconium zinc stannum oxide (ZrₓZn_{y}Sn_{z}O), stannum oxide (SnₓO), hafnium indium zinc oxide (HfₓIn_{y}Zn_{z}O), gallium zinc stannum oxide (GaₓZn_{y}Sn_{z}O), aluminum zinc stannum oxide (AlₓZn_{y}Sn_{z}O), ytterbium gallium zinc oxide (YbₓGa_{y}Zn_{z}O), indium gallium oxide (InₓGa_{y}O), etc.

As shown in FIG. 2, in some implementations, semiconductor layer 226 has two ends (the upper end and lower end) in the vertical direction (the z-direction), and both ends extend beyond the gate structure, respectively, in the vertical direction (the z-direction) into ILD layers. That is, semiconductor layer 226 can have a larger vertical dimension (e.g., the depth) than that of the gate structure (e.g., in the z-direction), and neither the upper end nor the lower end of semiconductor layer 226 is flush with the respective end of the gate structure. Thus, short circuits between bit lines and word lines/gate electrode layers or between word lines/gate electrode layers and capacitors can be avoided.

As shown in FIG. 2, in some implementations, vertical transistor 220 can further include a source and a drain disposed at the two ends (the upper end and lower end) of semiconductor layer 226, respectively, in the vertical direction (the z-direction). In some implementations, one of the source and drain (e.g., at the lower end in FIG. 2) is coupled to capacitor 210, and the other one of the source and drain (e.g., at the upper end in FIG. 2) is coupled to bit line 228. Ohmic contacts are established between the drain and the bit line, as well as between the source and capacitor 210, using metal electrodes with enhanced electron concentration to ensure adequate carrier availability.

In some implementations, the drains (the upper ends of semiconductor layers 226) of two adjacent vertical transistors 220 are connected and coupled to a common bit line 228. In the z-y plane cross-section, the connected semiconductor layers 226 of two adjacent vertical transistors 220 form an inverted U-shaped structure. An insulating wall 230 between the adjacent vertical transistors 220 is positioned within the interior of this inverted U-shaped configuration. The gate structures of the two adjacent vertical transistors 220 are symmetrically located on the exterior sides of the inverted U-shaped structure. In some embodiments, semiconductor layer 226 includes an extending portion that protrudes along the y-direction from the source end (the lower end of semiconductor layer 226). This extending portion is electrically connected to the capacitor 210. The contact area between capacitor 210 and vertical transistor 220 corresponds to the area of the extending portion on the x-y plane. This contact area is significantly larger—by a multiple—than the area of the end of semiconductor layer 226 on the x-y plane. As a result, the increased contact area substantially reduces the contact resistance between capacitor 210 and vertical transistor 220.

In some implementations, the gate structure includes a gate dielectric layer 224 and a gate electrode layer 222. In some implementations, gate dielectric layer 224 includes dielectric materials, such as silicon oxide, silicon nitride, or high-k dielectrics including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof. In some implementations, gate electrode layer 222 includes conductive materials including, but not limited to, W, Co, Cu, Al, TiN, TaN, polysilicon, silicide, or any combination thereof. In some implementations, gate electrode layer 222 includes multiple conductive layers, such as a W layer over a TiN layer. In one example, the gate structure may be a “gate oxide/gate poly” gate in which gate dielectric layer 224 includes silicon oxide and gate electrode layer includes doped polysilicon. In another example, the gate structure may be a high-k metal gate (HKMG) in which gate dielectric layer 224 includes a high-k dielectric, and the gate electrode layer includes a metal.

In some implementations, gate electrode layer 222 may be part of a word line or extend in the word line direction (e.g., the x-direction in FIG. 2) as a word line (referred to as 222 as well), although not directly shown in FIG. 2, semiconductor device 200 can also include a plurality of word lines each extending in the word line direction (the x-direction). Each word line 222 can be coupled to a row of DRAM cells. That is, bit line 228 and word line 222 can extend in two perpendicular lateral directions, and semiconductor layer 226 of vertical transistor 220 can extend in the vertical direction perpendicular to the two lateral directions in which bit line 228 and word line 222 extend. As shown in FIG. 2, vertical transistor 220 extends vertically through and is coupled with a corresponding word line 222, and the source or drain of vertical transistor 220 at the upper end thereof is coupled with bit line 228 directly, according to some implementations. In some implementations, word lines 222 include conductive materials including, but not limited to, W, Co, Cu, Al, TiN, TaN, polysilicon, silicide, or any combination thereof. In some implementations, word line 222 includes multiple conductive layers, such as a W layer over a TiN layer.

In some implementations, the rows of vertical transistors 220 separated by insulating wall 230 are mirror-symmetric to one another with respect to insulating wall 230. Insulating wall 230 can be formed with dielectric materials including, but not limited to, silicon oxide, silicon nitride, silicon oxynitride, low-k dielectrics, or any combination thereof. It is understood that insulating wall 230 may include an air gap each disposed laterally between adjacent semiconductor layers 226. As described below with respect to the fabrication process, air gaps may be formed due to the relatively small pitches of vertical transistors 220 in the bit line direction (e.g., the y-direction). On the other hand, the relatively large dielectric constant of air in air gaps (e.g., about 4 times the dielectric constant of silicon oxide) can improve the insulation effect between vertical transistors 220 compared with some dielectrics (e.g., silicon oxide). Similarly, in some implementations, air gaps are formed laterally between word lines/gate electrode layers 222 in the bit line direction as well, depending on the pitches of word lines/gate electrode layers 222 in the bit line direction.

In some implementations, insulating wall 230 includes a conductor layer 234 encased in a dielectric layer. The conductor layers 234 in semiconductor device 200 are connected to a common ground, preventing charge accumulation between adjacent vertical transistors 220. This configuration significantly reduces electrical coupling between the semiconductor layers 226 of the two neighboring vertical transistors 220. In some implementations, conductor layer 234 includes conductive materials including, but not limited to, W, Co, Cu, Al, TiN, TaN, polysilicon, silicide, or any combination thereof. In some implementations, conductor layer 234 includes multiple conductive layers, such as a W layer over a TiN layer.

As shown in FIG. 2, the dielectric layer includes a first dielectric layer 232 under conductor layer 234, a second dielectric layer 236 on conductor layer 234, a left sidewall 238 on the left of conductor layer 234 to separate the conductor layer from a first vertical transistor on the left, and a right sidewall 238 (refers as 238 as well) on the right of conductor layer 234 to separate conductor layer 234 from a second vertical transistor on the right. That is, conductor layer 234 is surrounded by the dielectric layer to be isolated from the adjacent semiconductor layers 226. In some implementations, the dielectric layer includes dielectric materials, such as silicon oxide, silicon nitride, or high-k dielectrics. In some implementations, the materials of first dielectric layer 232, second dielectric layer 236, left sidewall 238, and right sidewall 238 can be identical or different. For example, first dielectric layer 232 may be silicon nitride, while second dielectric layer 236, left sidewall 238, and right sidewall 238 can be silicon oxide.

As shown in FIG. 2, in some implementations, capacitor 210 includes a first electrode 208 above and coupled with source or drain of vertical transistor 220, a capacitor dielectric 204 above and coupled with first electrode 208, and a second electrode 206 above and coupled with capacitor dielectric 204. That is, capacitor 210 can be a vertical capacitor in which first and second electrodes 208 and 206 and capacitor dielectric 204 are stacked vertically (in the z-direction), and capacitor dielectric 204 can be sandwiched between first and second electrodes 208 and 206. In some implementations, each first electrode 208 is coupled to the source or drain of a respective vertical transistor 220 in the same DRAM cell, while all second electrodes 206 are parts of a common plate connected to the ground, e.g., a common ground. In some implementations, first electrode 208 and/or the second electrode 206 can include conductive materials including, but not limited to, W, Co, Cu, Al, TiN, TaN, polysilicon, silicide, or any combination thereof. In some implementations, capacitor dielectric 204 includes dielectric materials, such as silicon oxide, silicon nitride, or high-k dielectrics including, but not limited to, Al₂O₃, HfO₂, Ta₂O₅, ZrO₂, TiO₂, or any combination thereof.

In some implementations, semiconductor device 200 further includes a source node contact (SNC) 212 positioned between vertical transistor 220 and capacitor 210. SNC 212 may include a metal electrode embedded within a via located in the interlayer dielectric layer (ILD) 214. One end of SNC 212 is connected to the source of vertical transistor 220, while the other end is connected to capacitor 210. The metal electrode is fabricated from highly conductive metals such as aluminum, copper, or molybdenum to establish reliable electrical contact with the source. SNC 212 may also include an interfacial layer (e.g., Ti or TiN) to enhance contact performance and prevent diffusion. During the operation of the vertical transistor 220, SNC 212 facilitates the injection of carriers (e.g., electrons) into the channel region, thereby reducing contact resistance between vertical transistor 220 and capacitor 210 and improving device performance. In some implementations, semiconductor device 200 further includes a substrate 202 disposed under DRAM cells. As described below with respect to the fabrication process, substrate 202 can be part of a carrier wafer. It is understood that in some examples, substrate 202 may not be included in semiconductor device 200.

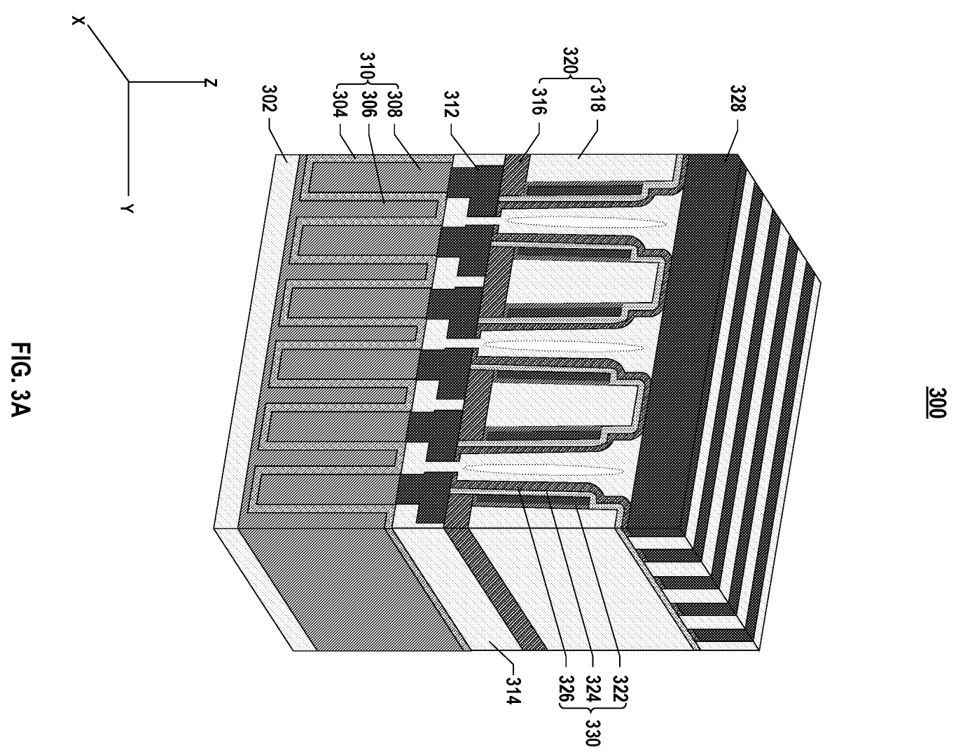

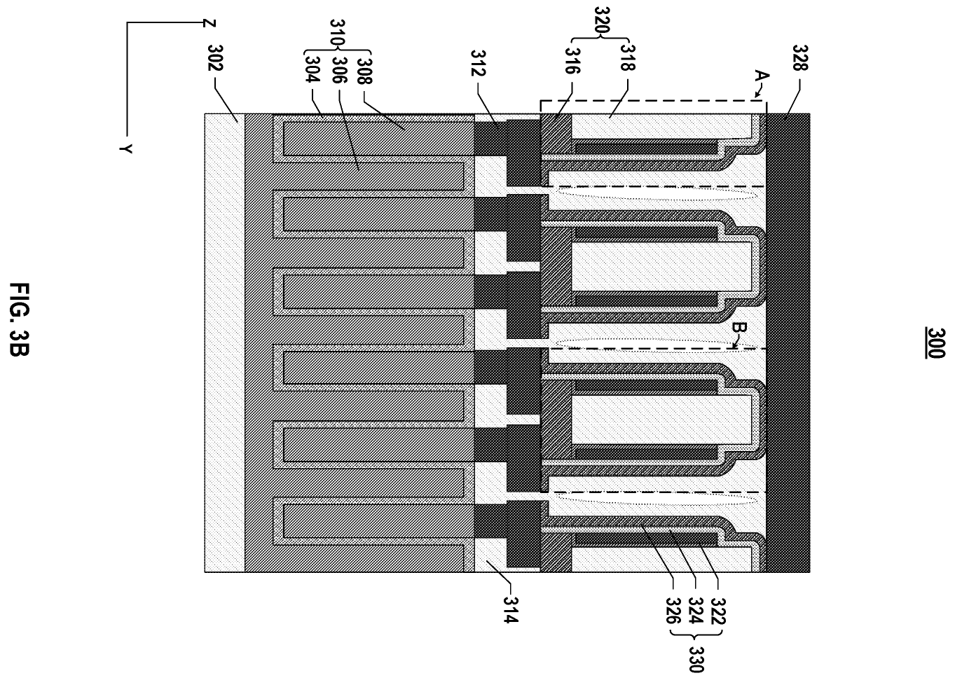

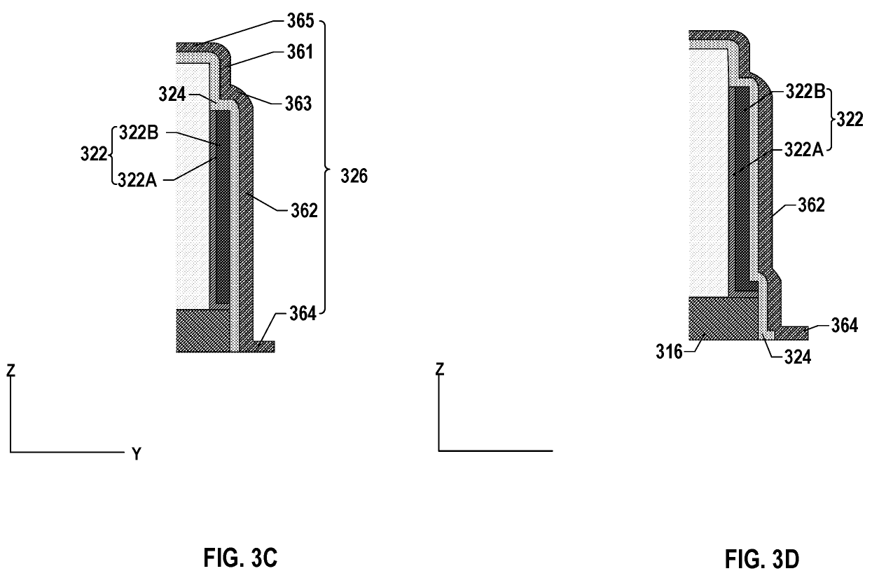

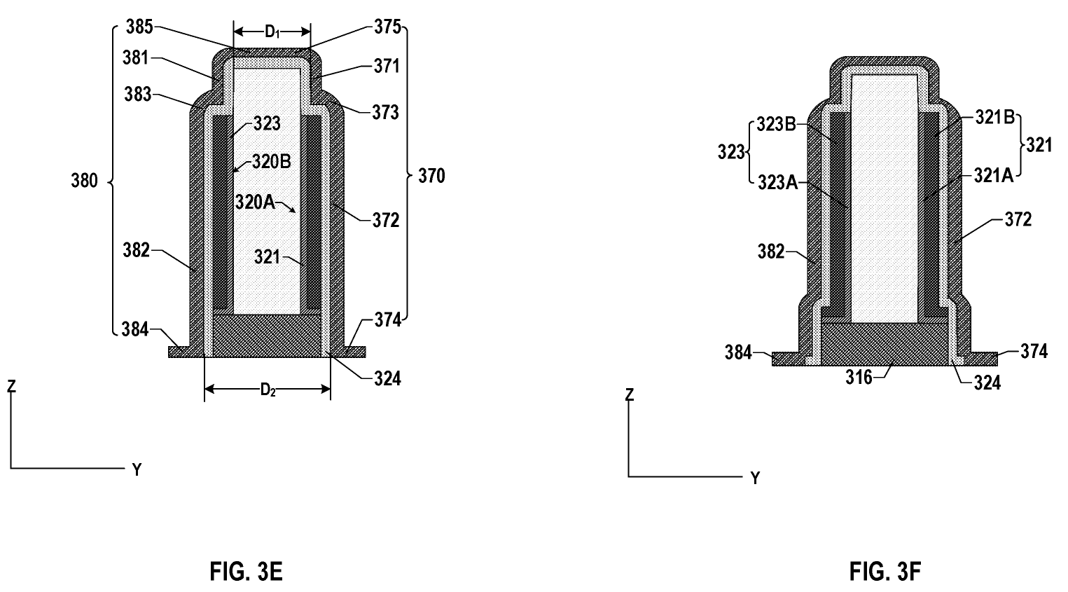

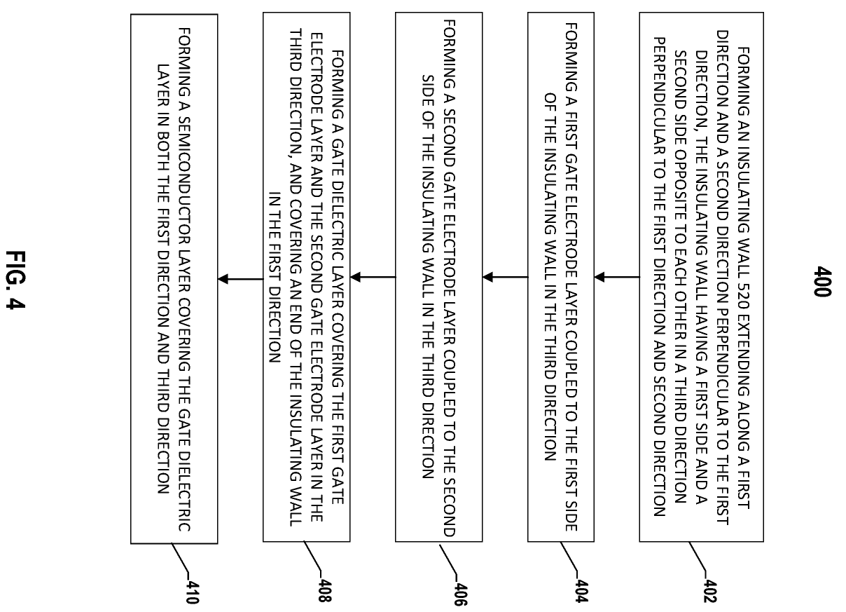

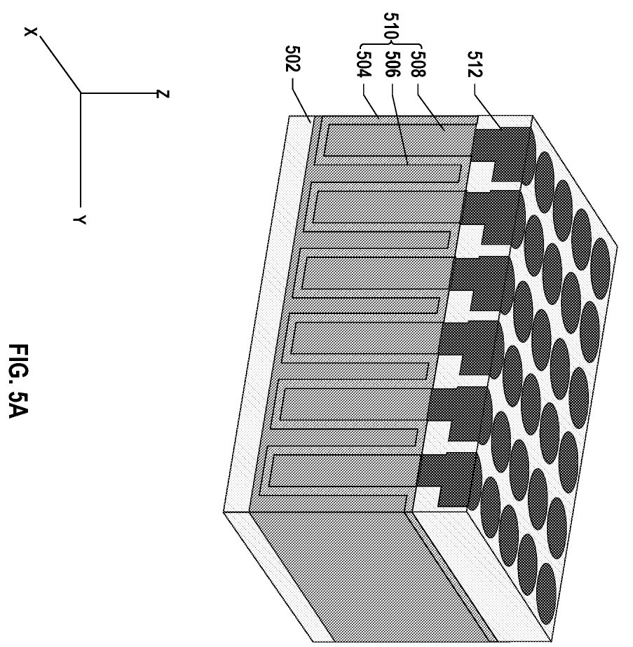

FIG. 3A illustrates a perspective view of a semiconductor device 300 according to some implementations of the present disclosure. FIG. 3B illustrates a cross-sectional view of semiconductor device 300 along the y-direction according to some implementations of the present disclosure. FIG. 3C is a partially enlarged view of region A in FIG. 3B. FIG. 3E is a partially enlarged view of region B in FIG. 3B. Semiconductor device 300 can be a DRAM device in which memory cells are provided as an array of DRAM cells. In some embodiments, each DRAM cell includes a capacitor 310 for storing a bit of data as a positive or negative electrical charge as well as one or more vertical transistors 330 (a.k.a. pass transistors) that control (e.g., switch and selecting) access to it. In some implementations, each DRAM cell is a one-transistor, one-capacitor (1T1C) cell. Since transistors always leak a small amount of charge, the capacitors will slowly discharge, causing information stored in them to drain. As such, a DRAM cell has to be refreshed to retain data according to some implementations. It is understood that the DRAM cells may be of any suitable configurations, such as 2T1C cell, 3T1C cell, etc.

Vertical transistor 330 can be a MOSFET used to switch a respective DRAM cell. In some implementations, vertical transistor 330 includes a semiconductor layer 326 (i.e., the active region in which multiple channels can form) extending vertically (in the z-direction) and a gate structure coupled with a plurality of sides of semiconductor layer 326.

In some embodiments, the semiconductor layer 326 exhibits a leakage value of less than a pico-ampere. For example, the semiconductor layer 326 may include a metal oxide semiconductor material. The conduction band orbitals of metal oxide semiconductor materials typically overlap, resulting in carrier mobility less dependent on the degree of ordering in the thin film material. As a result, metal oxide semiconductors exhibit a mobility range of approximately 1 to 100 cm²·V⁻¹·s⁻¹, significantly higher than silicon. This property contributes to superior electrical uniformity compared to silicon. Additionally, metal oxide semiconductors are compatible with low-temperature processing, making them suitable for integration with amorphous silicon (a-Si) thin-film transistor (TFT) processes. This compatibility enables fabrication on flexible plastic substrates and facilitates low-cost manufacturing, as ion implantation and crystallization equipment are not required.

In a vertical structure, metal oxide semiconductor materials offer unique advantages, including the ability to achieve short channel lengths, reduce device footprint, and mitigate mechanical stress in flexible substrates. Even when cracks form in the channel layer due to compressive or tensile strain, carriers can still transport efficiently in the vertical direction. These characteristics make metal oxide semiconductors particularly promising for flexible electronics applications. In some implementations, semiconductor layer 326 can be one or more of indium gallium zinc oxide (InₓGa_{y}Zn_{z}O), indium gallium silicon oxide (InₓGa_{y}Si_{z}O), indium stannum zinc oxide (InₓSn_{y}Zn_{z}O), indium zinc oxide (InₓZn_{y}O), zinc oxide (ZnₓO), zinc stannum oxide (ZnₓSn_{y}O), zinc oxide nitride (ZnₓO_{y}N), zirconium zinc stannum oxide (ZrₓZn_{y}Sn_{z}O), stannum oxide (SnₓO), hafnium indium zinc oxide (HfₓIn_{y}Zn_{z}O), gallium zinc stannum oxide (GaₓZn_{y}Sn_{z}O), aluminum zinc stannum oxide (AlₓZn_{y}Sn_{z}O), ytterbium gallium zinc oxide (YbₓGa_{y}Zn_{z}O), indium gallium oxide (InₓGa_{y}O), etc.

As shown in FIGS. 3A and 3B, in some implementations, semiconductor layer 326 has two ends (the upper end and lower end) in the vertical direction (the z-direction), and both ends extend beyond the gate structure, respectively, in the vertical direction (the z-direction) into ILD layers. That is, semiconductor layer 326 can have a larger vertical dimension (e.g., the depth) than that of the gate structure (e.g., in the z-direction), and neither the upper end nor the lower end of semiconductor layer 326 is flush with the respective end of the gate structure. Thus, short circuits between bit lines and word lines/gate electrode layers or between word lines/gate electrode layers and capacitors can be avoided.

In some implementations, as shown in FIGS. 3A and 3B, vertical transistor 330 can further include a source and a drain disposed at the two ends (the upper end and lower end) of semiconductor layer 326, respectively, in the vertical direction (the z-direction). In some implementations, one of the source and drain (e.g., at the lower end in FIG. 3B) is coupled to capacitor 310, and the other one of the source and drain (e.g., at the upper end in FIG. 3B) is coupled to bit line 328. Ohmic contacts are established between the drain and the bit line, as well as between the source and capacitor 310, using metal electrodes with enhanced electron concentration to ensure adequate carrier availability.

In some implementations, the gate structure includes a gate dielectric layer 324 and a gate electrode layer 322. Along the y-direction, gate electrode layer 322 and semiconductor layer 326 are positioned on opposite sides of gate dielectric layer 324. Specifically, gate electrode layer 322 is located on a first side of gate dielectric layer 324, while semiconductor layers 326 are situated on a second side. The first and second sides are oriented opposite each other along the y-direction. In some implementations, gate dielectric layer 324 includes dielectric materials, such as silicon oxide, silicon nitride, or high-k dielectrics including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof.

In some implementations, gate electrode layer 322 includes conductive materials including, but not limited to, W, Co, Cu, Al, TiN, TaN, polysilicon, silicide, or any combination thereof. In some implementations, gate electrode layer 322 includes multiple conductive layers, such as a two-layer structure including TiN/TaN, TaN/Al, TiN/Al, or W/Cu, or a three-layer structure including TiN/TaN/Al or Mo/TiN/Al. In some implementations, as shown in FIGS. 3B and 3C, gate electrode layer 322 includes a first layer 322A and a second layer 322B coupled to first layer 322A in the third direction, i.e., the y-direction. First layer 322A is coupled to insulating wall 320, and second layer 322B is coupled to gate dielectric layer 324.

As shown in FIGS. 3C and 3D, in some implementations, due to the difference between the widths of first portion 316 and second portion 318 of insulating wall 320 in the y-direction, at least one of first layer 322A and second layer 322B has an “L-shaped” cross-section in the y-z plane in response to a width of gate electrode layer 322 is smaller than the width difference. Referring to FIG. 3C, in some implementations, first layer 322A has an “L-shaped” cross-section and includes a first sub-layer extending along the z-direction and a second sub-layer connected to an end of the first sub-layer and extending along the y-direction. The second sub-layer of first layer 322A is located between the first sub-layer of gate electrode layer 322 and semiconductor layer 326. In some implementations, referring to FIG. 3D, both first layer 322A and second layer 322B have an L-shaped cross-section in the y-z plane. Second layer 322B of gate electrode layer 322 includes a first sub-layer extending along the z-direction and a second sub-layer connected to an end of the first sub-layer and extending along the y-direction. The second sub-layer of second layer 322B is between the first sub-layer of second layer 322B and semiconductor layer 326.

In one example, the gate structure may be a “gate oxide/gate poly” gate in which gate dielectric layer 324 includes silicon oxide and gate electrode layer includes doped polysilicon. In another example, the gate structure may be a high-k metal gate (HKMG) in which gate dielectric layer 324 includes a high-k dielectric, and the gate electrode layer includes a metal.

In some implementations, gate electrode layer 322 may be part of a word line or extend in the word line direction (e.g., the x-direction) as a word line (referred to as 322), although not directly shown in FIGS. 3A and 3B, semiconductor device 300 can also include a plurality of word lines extending in the word line direction (the x-direction). Each word line 322 can be coupled to a row of DRAM cells. That is, bit line 328 and word line 322 can extend in two perpendicular lateral directions, and semiconductor layer 326 of vertical transistor 330 can extend in the vertical direction perpendicular to the two lateral directions in which bit line 328 and word line 322 extend. As shown in FIGS. 3A and 3B, vertical transistor 330 extends vertically through and is coupled with a corresponding word line 322, and the source or drain of vertical transistor 330 at the upper end is coupled with bit line 328 directly, according to some implementations. In some implementations, word lines 322 include conductive materials including, but not limited to, W, Co, Cu, Al, TiN, TaN, polysilicon, silicide, or any combination thereof. In some implementations, word line 322 includes multiple conductive layers, such as a W layer over a TiN layer.

In some implementations, the rows of vertical transistors 330 separated by insulating wall 320 are mirror-symmetric to one another with respect to insulating wall 320. Insulating wall 320 can be formed with dielectric materials including, but not limited to, silicon oxide, silicon nitride, silicon oxynitride, low-k dielectrics, or any combination thereof. It is understood that insulating wall 320 may include an air gap each disposed laterally between adjacent semiconductor layers 326. In some implementations, insulating wall 320 includes a conductor layer encased in a dielectric layer. The multiple conductor layers in semiconductor device 300 are connected to a common ground, preventing charge accumulation between adjacent vertical transistors 330. In some implementations, the conductor layer includes multiple conductive layers, such as a W layer over a TiN layer.

In some implementations, insulating wall 320 along the z-direction includes a first portion 316 and a second portion 318 made of different insulating materials. In the y-direction, the widths of first portion 316 and second portion 318 differ. As shown in FIGS. 3A and 3B, the width of first portion 316 in the y-direction is equal to the width of second portion 318 plus the widths of the two gate electrode layers 322 of vertical transistors 330 located on either side of insulating wall 320. Additionally, in the z-direction, the height of gate electrode layer 322 is less than that of semiconductor layer 326, allowing the end of semiconductor layer 326 to extend beyond gate electrode layer 322. This means the semiconductor layer 326 can have a greater vertical dimension than gate electrode layer 322. In some cases, neither the upper nor lower end of semiconductor layer 326 flush with the respective ends of gate electrode layer 322, thus preventing short circuits between bit lines 328 and word lines/gate electrode layers 322 or between word lines/gate electrode layers 322 and capacitors 310.

In some implementations, semiconductor layers 326 of each vertical transistor 330 include a first portion 361, a second portion 362, and a third portion 363. First portion 361 extends along the z-direction and overlaps with gate electrode layer 322 in that direction. It contacts the second side of gate dielectric layer 324, opposite to the first side, and does not overlap with the gate electrode layer in the y-direction, as illustrated in FIGS. 3A and 3B. The first side of gate dielectric layer 324 is in contact with gate electrode layer 322. Second portion 362 also contacts the second side of gate dielectric layer 324 and overlaps with gate electrode layer 322 in the y-direction while not overlapping in the z-direction. In some implementations, both ends of second portion 362 extend beyond the ends of gate electrode layer 322 in the z-direction. The height of second portion 362 is greater than that of gate electrode layer 322.

Since first portion 361 and second portion 362 do not overlap in the y-direction nor the z-direction, a third portion 363 is required to connect the first portion 361 to the second portion 362. Referring to FIGS. 3A, 3B, and 3C, third portion 363 extends at least along a fourth direction. The fourth direction is different from the first and second directions (i.e., the z-direction and the x-direction) because first portion 361 and second portion 362 misalign with each other in both two directions. In some implementations, the fourth direction may be parallel to the y-direction to bridge the gap between first portion 361 and second portion 362 in the y-direction. Alternatively, the fourth direction may differ from the y-direction, as various factors such as processing and design considerations may result in a distance between first portion 361 and second portion 362 in the y-direction. In some implementations, to bridge the gap between first portion 361 and second portion 362 in the y-direction and the z-direction, third portion 363 is stepped-shaped or curved. Third portion 363 may be any suitable shape according to the locations and shapes of first portion 361 and second portion 362. It is understood that FIGS. 3A, 3B, and 3C, are for illustrative purposes only and may not necessarily reflect the actual device structure (e.g., semiconductor layer 326) in practice.

In some implementations, semiconductor layer 326 includes a fourth portion 364. Fourth portion 364 is in contact with an end of second portion 362 away from first portion 361 and extending along the y-direction. Fourth portion 364 is located on the second side of gate dielectric layer 324 and extends away from gate electrode layer 322. In some embodiments, fourth portion 364 protrudes along the y-direction from the source end (the lower end of semiconductor layer 226). Fourth portion 364 is electrically connected to the capacitor 310. The contact area between capacitor 310 and vertical transistor 330 corresponds to the area of the extending portion on the x-y plane. This contact area is significantly larger—by a multiple than the area of the end of semiconductor layer 326 on the x-y plane. As a result, the increased contact area substantially reduces the contact resistance between capacitor 310 and vertical transistor 330.

In some implementations, semiconductor layer 326 includes a fifth portion 365 in contact with an end of first portion 361 away from second portion 362 and extending along the y-direction. Fifth portion 365 of vertical transistor 330 is in contact with a fifth portion 365 of an adjacent vertical transistor 330, as shown in FIG. 3C. The drains (the upper ends of semiconductor layers 326) of two adjacent vertical transistors 330 are connected and coupled to a common bit line 328. In some implementations, semiconductor layer 326 does not include the fifth portion, and semiconductor layer 326 of each vertical transistor 330 is isolated from semiconductor layer 326 of adjacent vertical transistor 330. In this situation, bit line 328 may contact first portion 361 of semiconductor layer 326 of each vertical transistor 330.

Gate dielectric layer 324 is located between gate electrode layer 322 and semiconductor layer 326. A minimum height of gate dielectric layer 324 in the z-direction is equal to or greater than a height of gate electrode layer 322 in the z-direction. In some implementations, the height of gate dielectric layer 324 in the z-direction is equal to that of gate electrode layer 322 in the z-direction. In some implementations, gate dielectric layer 324 has the same shape as semiconductor layer 326, and the height of gate dielectric layer 324 is the same as that of semiconductor layer 326, as shown in FIG. 3C.

In some implementations, gate dielectric layer 324 and semiconductor layer 326 have a stair-shaped cross-section in the y-z plane due to the L-shaped gate electrode layer 322, as discussed above. Referring to FIG. 3D, in response to the width of gate electrode layer 322 is smaller than the width difference between first portion 316 and second portion 318 of insulating wall 320, second portion 362 of semiconductor layer 326 protrudes at a first end close to fourth portion 364 with respective to the rest of second portion 362. Second portion 318 is stair-shaped in the y-z plane. In this situation, semiconductor layer 326 has a stair-shaped cross-section with multiple steps, as shown in FIG. 3D.

In some implementations, as illustrated in FIGS. 3A, 3B, and 3E, two adjacent vertical transistors 330 can be considered a single semiconductor device . The arrangement of semiconductor layers 326 of vertical transistors 330 can be described more clearly from this perspective. As shown in FIG. 3E, semiconductor device includes an insulating wall 320 extending along the z-direction and the x -direction. Insulating wall 320 has a first side 320A and a second side 320B opposite each other in the y -direction. Semiconductor device includes a first gate electrode layer 321 coupled to first side 320A of insulating wall 320 in the y -direction, a second gate electrode layer 323 coupled to second side 320B of insulating wall 320 in the y -direction. Semiconductor device includes a gate dielectric layer 324 covering first gate electrode layer 321 and second gate electrode layer 323 in the y -direction and covering an end of insulating wall 320 in the z -direction. Semiconductor device further includes a first semiconductor layer 370 and a second semiconductor layer 380. First semiconductor layer 370 covers dielectric gate layer 324, and first gate electrode layer 321 in the z-direction and the x -direction. Second semiconductor layer 380 covers dielectric gate layer 324 and second gate electrode layer 323 in the z-direction and the x -direction.

In some implementations, as shown in FIGS. 3A, 3B, and 3E, first semiconductor layer 370 includes a first end coupled to a first bit line, and a second end connected to capacitor 310. Second semiconductor layer 380 includes a first end coupled to the first bit line, and a second end coupled to capacitor 310. In some implementations, the first end of first semiconductor layer 370 and the first end of second semiconductor layer 380 are connected and coupled to a common bit line. In some implementations, referring to FIG. 3E, a first distance D₁ between the first end of first semiconductor layer 370 and the first end of second semiconductor layer 380 is smaller than a second distance D₂ between the second end of first semiconductor layer 370 and the second end of second semiconductor layer 380. In some implementations, the difference between first distance D₁ and second distance D₂ is substantially equal to a sum of a thickness of first gate electrode layer 321 and a thickness of second gate electrode layer 323. In some implementations, the difference between first distance D₁ and second distance D₂ is greater than the sum of the thicknesses of first gate electrode layer 321 and second gate electrode layer 323 as affected by the fabricating processes.

As shown in FIG. 3E, first semiconductor layer 370 includes several sections: a first section 371, a second section 372, and a third section 373, which are formed adjacent to first side 320A of the insulating wall 320. Second semiconductor layer 380 includes a fourth section 381, a fifth section 382, and a sixth section 383, which are formed adjacent to second side 320B of insulating wall 320. In some implementations, first semiconductor layer 370 and second semiconductor layer 380 are connected together and coupled with a common bit line. In some implementations, first semiconductor layer 370 and second semiconductor layer 380 are separated.

First section 371 extends along the z -direction and overlaps with first gate electrode layer 321 in the y -direction. In some implementations, gate dielectric layer 324 is located between first section 371 and first side 320A of insulating wall 320. In some implementations, first section 371 directly connects with first side 320A of insulating wall 320. First section 371 overlaps with gate electrode layer 322 in the y-direction while not overlapping in the z-direction. In some implementations, both ends of first section 371 extend beyond the ends of gate electrode layer 322 in the z-direction. The height of second portion 362 is greater than that of gate electrode layer 322.

Second section 372 extends along the z -direction and overlaps with the first gate electrode layer 321 in the z -direction. Gate dielectric layer 324 and gate electrode layer 322 are located between second section 372 and first side 320A of insulating wall 320. Therefore, second section 372 does not overlap with first gate electrode layer 321 in the y-direction, as illustrated in FIG. 3E.

Since first section 371 and second section 372 do not overlap in the y-direction nor the z-direction, a third section 373 is required to connect the first section 371 to the second section 372. Referring to FIG. 3E, third section 373 extends at least along a fourth direction. The fourth direction is different from the first and second directions (i.e., the z-direction and the x-direction) because first section 371 and second section 372 misalign with each other in both directions. In some implementations, the fourth direction may parallel the y-direction to bridge the gap between first section 371 and second section 372 in the y-direction. Alternatively, the fourth direction may differ from the y-direction, as various factors such as processing and design considerations may result in a distance between first section 371 and second section 372 in the y-direction. In some implementations, to bridge the gap between first section 371 and second section 372 in the y-direction and the z-direction, third section 373 is stepped-shaped or curved. Third section 373 may be any suitable shape according to the locations and shapes of first section 371 and second section 372. It is understood that FIGS. 3A, 3B, and 3E, are for illustrative purposes only and may not necessarily reflect the actual device structure in practice.

Fourth section 381 extends along the z -direction and overlaps with second gate electrode layer 323 in the y -direction. In some implementations, gate dielectric layer 324 is located between fourth section 381 and second side 320B of insulating wall 320. In some implementations, fourth section 381 connects directly with second side 320B of insulating wall 320. Fourth section 381 overlaps with gate electrode layer 322 in the y-direction while not overlapping in the z-direction. In some implementations, both ends of fourth section 381 extend beyond the ends of gate electrode layer 322 in the z-direction. That is, the height of second portion 362 is greater than that of gate electrode layer 322.

Fifth section 382 extends along the z -direction and overlaps with the second gate electrode layer 323 in the z -direction. Gate dielectric layer 324 and second gate electrode layer 323 are located between fifth section 382 and second side 320B of insulating wall 320, therefore fifth section 382 does not overlap with second gate electrode layer 323 in the y-direction, as illustrated in FIG. 3E.

Since the fourth section 381 and fifth section 382 do not overlap in the y-direction nor the z-direction, a sixth section 383 is required to connect fourth section 381 to fifth section 382. Referring to FIG. 3E, sixth section 383 extends at least along a fourth direction. The fourth direction is different from the first and second directions (i.e., the z-direction and the x-direction) because fourth section 381 and fifth section 382 misalign with each other in both two directions. In some implementations, the fourth direction may be parallel to the y-direction to bridge the gap between fourth section 381 and fifth section 382 in the y-direction. Alternatively, the fourth direction may differ from the y-direction, as various factors such as processing and design considerations may result in a distance between fourth section 381 and fifth section 382 in the y-direction. In some implementations, to bridge the gap between fourth section 381 and fifth section 382 in the y-direction and the z-direction, sixth section 383 is stepped-shaped or curved. Sixth section 383 may be any suitable shape according to the locations and shapes of fourth section 381 and fifth section 382. It is understood that FIGS. 3A, 3B, and 3E, are for illustrative purposes only and may not necessarily reflect the actual device structure in practice.

In some implementations, first semiconductor layer 370 includes a seventh section 374. Seventh section 374 is in contact with an end of second section 372 away from first section 371 and extending along the y-direction. Seventh section 374 is located adjacent to first side 320A of insulating wall 320 and extending away from first gate electrode layer 321. In some embodiments, seventh section 374 protrudes along the y-direction from the lower end of second section 372. Seventh section 381 is electrically connected to capacitor 310. In some implementations, second semiconductor layer 380 includes an eighth section 384. Eighth section 384 is in contact with an end of fifth section 382 away from fourth section 381 and extending alone in the y-direction. Eighth section 384 is located adjacent to second side 320B of insulating wall 320 and extending away from second gate electrode layer 323. In some embodiments, eighth section 384 protrudes along the y-direction from the lower end of fifth section 382. Eighth section 384 is electrically connected to capacitor 310.

In some implementations, first semiconductor layer 370 further includes a ninth section 375 in contact with an end of first section 371 away from second section 372 and extending toward second semiconductor layer 380 along the y-direction. Ninth section 375 is in contact with second semiconductor layer 380. In some implementations, second semiconductor layer 380 further includes a tenth section 385 in contact with an end of fourth section 381 away from fifth section 382 and extending toward the first semiconductor layer along the third direction. Tenth section 385 is in contact with first semiconductor layer 370. In some implementations, as shown in FIG. 3E, ninth section 375 of first semiconductor layer 370, and tenth section 385 of second semiconductor layer 380 are in contact with each other and are coupled to a common bit line.

In some implementations, first gate electrode layer 321 and second gate electrode layer 323 include conductive materials including, but not limited to, W, Co, Cu, Al, TiN, TaN, polysilicon, silicide, or any combination thereof. In some implementations, first gate electrode layer 321 and second gate electrode layer 323 include multiple conductive layers, such as a two-layer structure including TiN/TaN, TaN/Al, TiN/Al, or W/Cu, or a three-layer structure including TiN/TaN/Al or Mo/TiN/Al.

In some implementations, as shown in FIGS. 3E and 3F, first gate electrode layer 321 includes a first layer 321A and a second layer 321B coupled to first layer 321A in the third direction, i.e., the y-direction. First layer 321A of first gate electrode layer 321 is coupled to insulating wall 320, and second layer 321B of first gate electrode layer 321 is coupled to gate dielectric layer 324.

As shown in FIGS. 3E and 3F, in some implementations, due to the difference between the widths of first portion 316 and second portion 318 of insulating wall 320 in the y-z plane, at least one of first layer 321A and second layer 321B has an “L-shaped” cross-section in the y-z plane in response to a width of first gate electrode layer 321 is smaller than the width differences. In some implementations, as shown in FIG. 3E, first layer 321A has an “L-shaped” cross-section and includes a first sub-layer extending along the z-direction and a second sub-layer connected to an end of the first sub-layer and extending along the y-direction. The second sub-layer of first layer 321A is located between the first sub-layer of first gate electrode layer 321 and first semiconductor layer 370. In some implementations, referring to FIG. 3F, both first layer 321A and second layer 321B have an L-shaped cross-section in the y-z plane. Second layer 321B of first gate electrode layer 321 includes a first sub-layer extending along the z-direction and a second sub-layer connected to an end of the first sub-layer and extending along the y-direction. The second sub-layer of second layer 322B is located between the first sub-layer of second layer 321B and first semiconductor layer 370.

In some implementations, gate dielectric layer 324 and first semiconductor layer 370 have a stair-shaped cross-section in the y-z plane due to the L-shaped first gate electrode layer 321, as discussed above. Referring to FIG. 3F, in response to the width of first gate electrode layer 321 is smaller than the width difference between first portion 316 and second portion 318 of insulating wall 320, second section 372 of first semiconductor layer 370 protrudes at a first end close to seventh section 374 with respective to the rest of second section 372. Second section 372 is stair-shaped in the y-z plane. In this situation, first semiconductor layer 370 has a stair-shaped cross-section with multiple steps, as shown in FIG. 3F.

In some implementations, second gate electrode layer 323 has a similar structure with first gate electrode 321 and will not repeat herein.

In some implementations, as shown in FIGS. 3E and 3F, second gate electrode layer 323 includes a first layer 323A and a second layer 323B coupled to first layer 323A in the third direction, i.e., the y-direction. First layer 323A of second gate electrode layer 323 is coupled to insulating wall 320, and second layer 323B of second gate electrode layer 323 is coupled to gate dielectric layer 324.

As shown in FIGS. 3E and 3F, at least one of first layer 323A and second layer 323B has an “L-shaped” cross-section in the y-z plane in response to a width of second gate electrode layer 323 is smaller than the width differences. In some implementations, as shown in FIG. 3E, first layer 323A has an “L-shaped” cross-section and includes a first sub-layer extending along the z-direction and a second sub-layer connected to an end of the first sub-layer and extending along the y-direction. The second sub-layer of first layer 323A is located between the first sub-layer of second gate electrode layer 323 and first semiconductor layer 370. In some implementations, referring to FIG. 3F, both first layer 323A and second layer 323B have an L-shaped cross-section in the y-z plane. Second layer 323B of second gate electrode layer 323 includes a first sub-layer extending along the z-direction and a second sub-layer connected to an end of the first sub-layer and extending along the y-direction. The second sub-layer of second layer 322B is located between the first sub-layer of second layer 323B and first semiconductor layer 370.

In some implementations, gate dielectric layer 324 and second semiconductor layer 380 have a stair-shaped cross-section in the y-z plane due to the L-shaped gate electrode layer 323, as discussed above. Referring to FIG. 3F, in response to the width of first gate electrode layer 323 is smaller than the width difference between first portion 316 and second portion 318 of insulating wall 320, fifth section 382 of second semiconductor layer 380 protrudes at a first end close to eighth section 384 with respective to the rest of fifth section 382. Fifth section 382 is stair-shaped in the y-z plane. In this situation, second semiconductor layer 380 has a stair-shaped cross-section with multiple steps, as shown in FIG. 3F.

As shown in FIG. 3, in some implementations, capacitor 310 includes a first electrode 308 above and coupled with source or drain of vertical transistor 330, a capacitor dielectric 304 above and coupled with first electrode 308, and a second electrode 306 above and coupled with capacitor dielectric 304. That is, capacitor 310 can be a vertical capacitor in which first and second electrodes 308 and 306 and capacitor dielectric 304 are stacked vertically (in the z-direction), and capacitor dielectric 304 can be sandwiched between first and second electrodes 308 and 306. In some implementations, each first electrode 308 is coupled to the source or drain of a respective vertical transistor 330 in the same DRAM cell, while all second electrode 306 are parts of a common plate coupled to the ground, e.g., a common ground. In some implementations, first electrode 308 and/or the second electrode 306 can include conductive materials including, but not limited to, W, Co, Cu, Al, TiN, TaN, polysilicon, silicide, or any combination thereof. In some implementations, capacitor dielectric 304 includes dielectric materials, such as silicon oxide, silicon nitride, or high-k dielectrics including, but not limited to, Al₂O₃, HfO₂, Ta₂O₅, ZrO₂, TiO₂, or any combination thereof.

In some implementations, semiconductor device 300 includes a source node contact (SNC) 312 positioned between vertical transistor 330 and capacitor 310. SNC 312 may include a metal electrode embedded within a via located in the interlayer dielectric layer (ILD) 314. One end of SNC 312 is connected to the source of vertical transistor 330, while the other is connected to capacitor 310. The metal electrode is fabricated from highly conductive metals such as aluminum, copper, or molybdenum to establish reliable electrical contact with the source. SNC 312 may also include an interfacial layer (e.g., Ti or TiN) to enhance contact performance and prevent diffusion. During the operation of the vertical transistor 330, SNC 312 facilitates the injection of carriers (e.g., electrons) into the channel region, thereby reducing the contact resistance between vertical transistor 330 and capacitor 310 and improving device performance.

In some implementations, semiconductor device 300 further includes a substrate 302 disposed under DRAM cells. As described below with respect to the fabrication process, substrate 302 can be part of a carrier wafer. It is understood that in some examples, substrate 302 may not be included in semiconductor device 300.

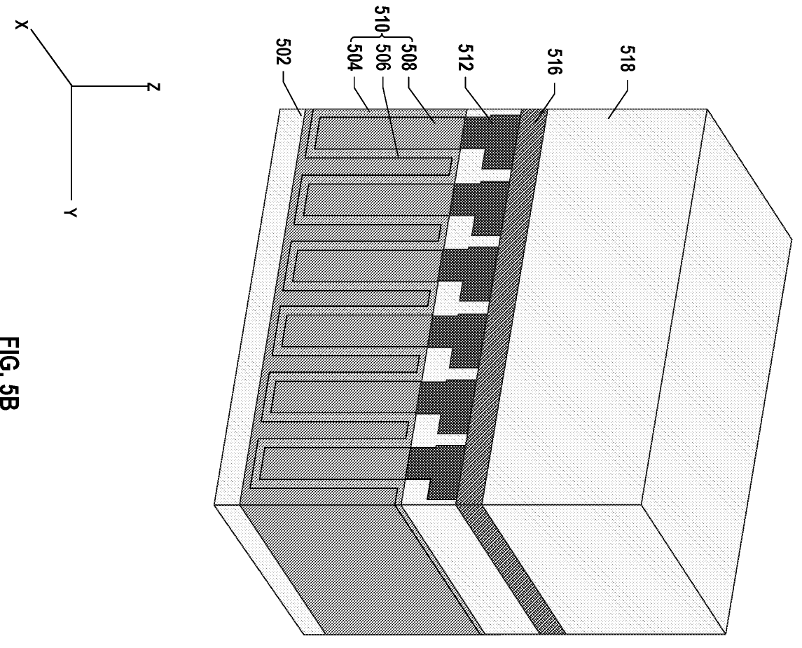

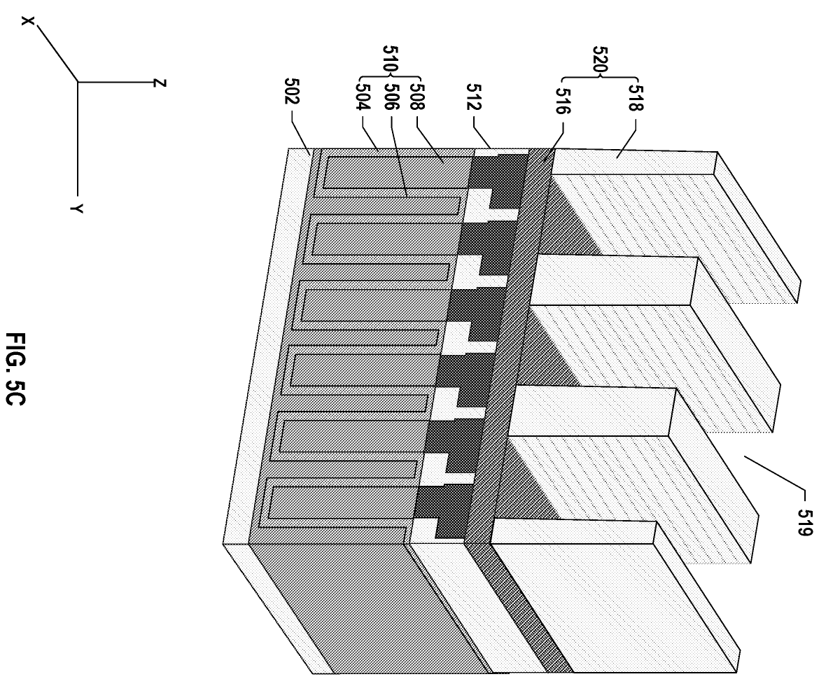

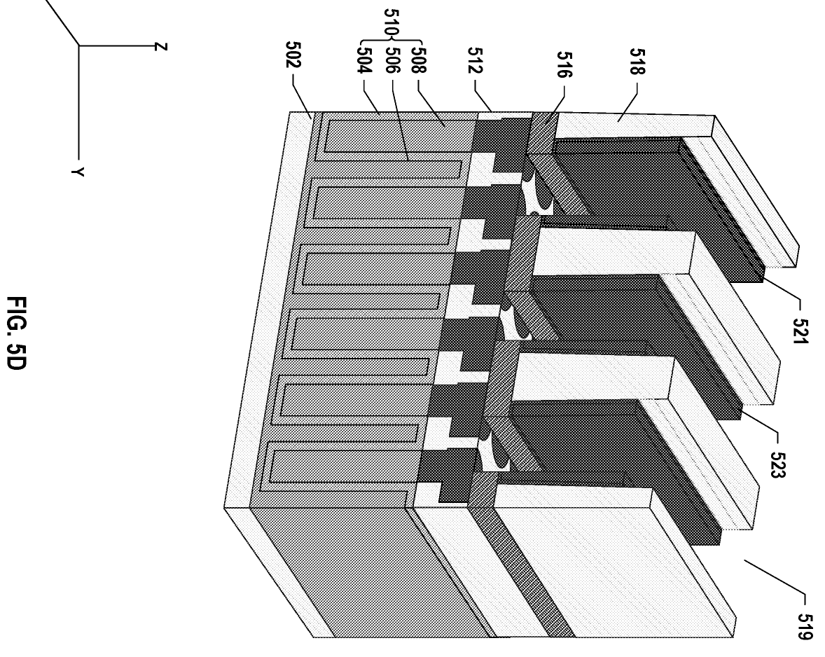

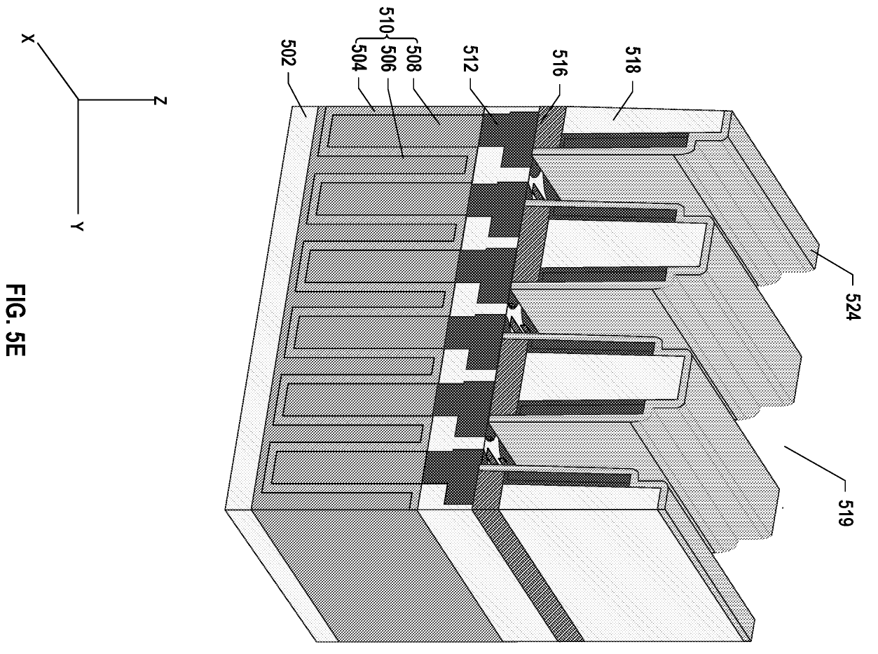

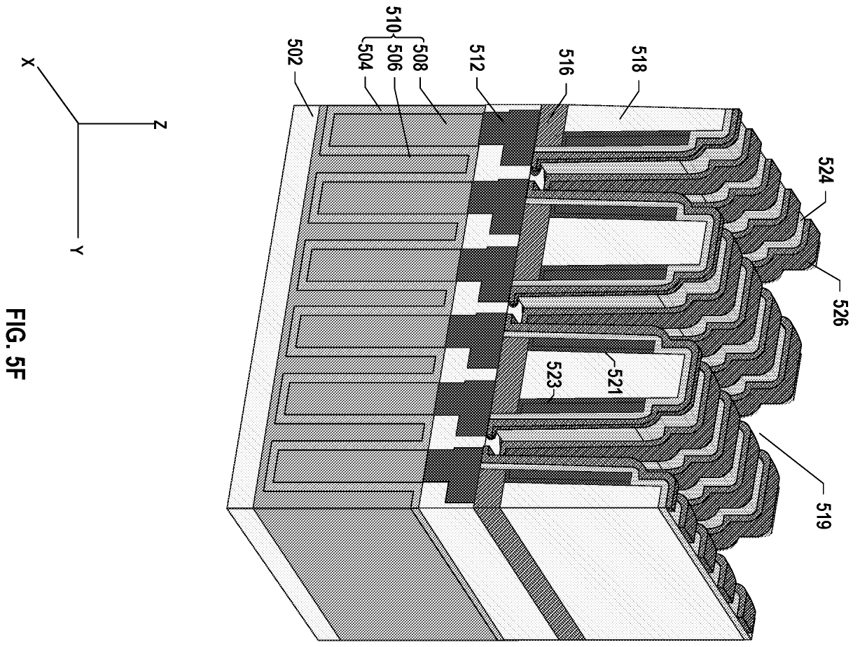

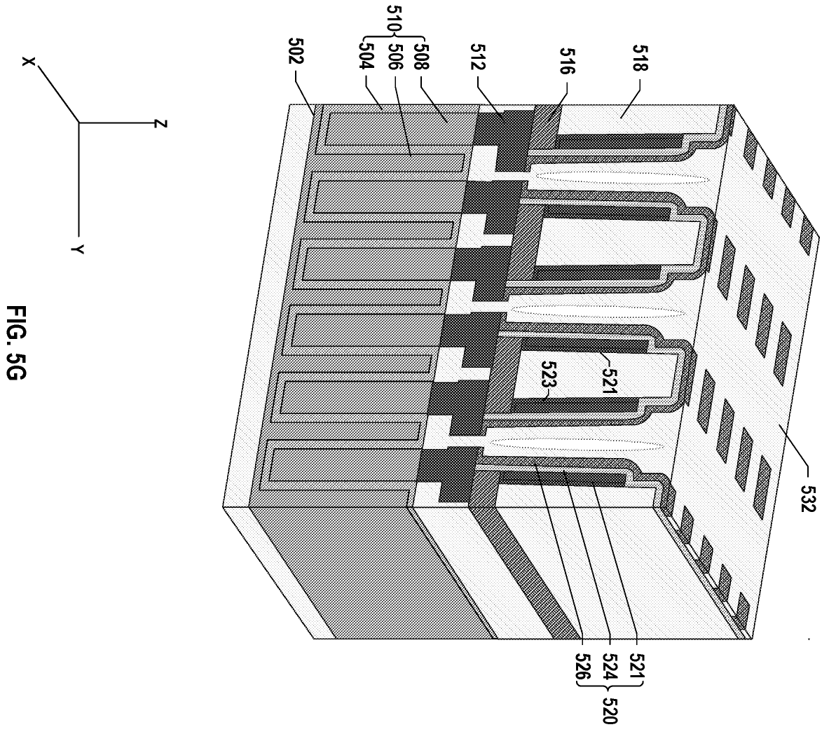

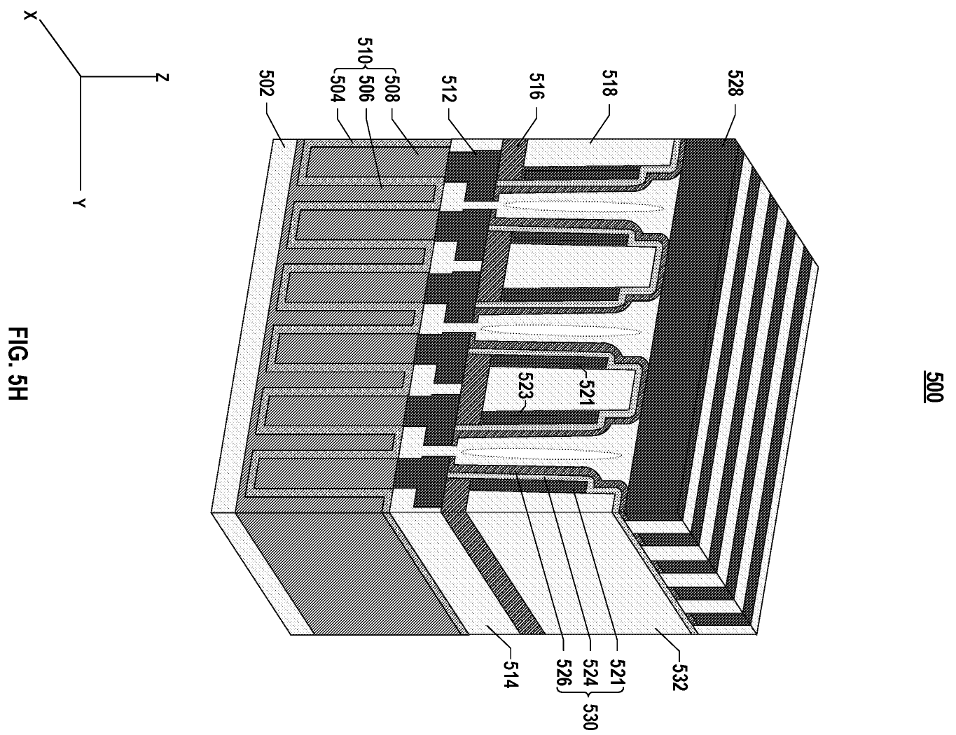

FIG. 4 illustrates a flowchart of a method 400 for forming a semiconductor device, including single-gate vertical transistors, such as semiconductor device 300, described above in connection with FIG. 3A, according to some implementations of the present disclosure. FIGS. 5A-5H illustrate a fabrication process for forming a semiconductor device 500 at certain fabricating stages of method 400 shown in FIG. 4, according to various implementations of the present disclosure. It is understood that the operations shown in method 400 are not exhaustive and that other operations can be performed before, after, or between any of the illustrated operations. Further, some operations may be performed simultaneously or in a different order than shown in FIG. 4.

Semiconductor device 500 includes an array of capacitors 510 and an array of vertical transistors 530 that are correspondingly coupled with the array of capacitors 510. In some implementations, the array of capacitors 510 can be formed before or after the array of vertical transistors 530. However, because the process of forming the array of capacitors 510 involves several high-temperature processes such as annealing, oxidation, and deposition, there is a risk of damaging semiconductor layer 526. To mitigate this risk, in some implementations, the array of capacitors 510 is formed first, followed by the formation of the array of vertical transistors 530.

In some implementations, as shown in FIG. 5A, in which a substrate 502 is formed. In some implementations, substrate 502 can be a semiconductor substrate, which can include silicon, silicon germanium (SiGe), gallium arsenide (GaAs), germanium (Ge), silicon-on-insulator (SOI), or any other suitable materials. In some other implementations, substrate 502 can be a carrier substrate, including any suitable semiconductor materials or an electrically non-conductive material, such as glass, plastic, or sapphire wafer. In some implementations, substrate 502 can be omitted.

In some implementations, capacitors 510 are formed on substrate 502. Capacitor 510 includes a first electrode 508 coupled with the source or drain of vertical transistor 530, a capacitor dielectric 504 coupled with first electrode 508, and a second electrode 506 coupled with capacitor dielectric 504. That is, capacitor 510 can be a vertical capacitor in which first electrode 508, second electrode 506, and capacitor dielectric 504 are stacked vertically (in the z-direction), and capacitor dielectric 504 can be sandwiched between first and second electrodes 508 and 506. In some implementations, each first electrode 508 is coupled to the source or drain of a respective vertical transistor 530 in the same DRAM cell, while all second electrodes 506 are parts of a common plate coupled to the ground, e.g., a common ground.

In some implementations, first electrodes 508 and/or the second electrode 506 can include conductive materials including, but not limited to, W, Co, Cu, Al, TiN, TaN, polysilicon, silicide, or any combination thereof. In some implementations, first electrodes 508 and/or second electrode 506 include a multiple-layer structure, each layer of the multiple-layer structure comprising one of TiN, TaN, carbon, polysilicon, metal compounds, and silicide. In some implementations, capacitor dielectric 504 includes dielectric materials, such as silicon oxide, silicon nitride, or high-k dielectrics including, but not limited to, Al₂O₃, HfO₂, Ta₂O₅, ZrO₂, TiO₂, or any combination thereof.

In some implementations, capacitors 510 can be formed by a series of fabricating processes including thin film deposition processes (e.g., CVD, PVD, ALD, etc.) and patterning processes (e.g., photoetching, dry etching, wet etching, cleaning, chemical mechanical polishing (CMP), etc.) It is noted that the fabricating processes and/or orders of forming capacitors 510 can be varied depending on a front-side process or a back-side process.

In some implementations, a plurality of source node contacts (SNCs) 512 formed above capacitors 510, as shown in FIG. 5A. SNCs 512 may include a metal electrode embedded within a via located in the interlayer dielectric layer (ILD) 514. One end of each SNC 512 is connected to the source of vertical transistor 530, while the other end is connected to capacitor 510. The metal electrode is fabricated from highly conductive metals such as aluminum, copper, or molybdenum to establish reliable electrical contact with the source. SNC 512 may also include an interfacial layer (e.g., Ti or TiN) to enhance contact performance and prevent diffusion. During the operation of the vertical transistor 530, SNC 512 facilitates the injection of carriers (e.g., electrons) into the channel region, thereby reducing contact resistance between vertical transistor 530 and capacitor 510 and improving device performance. In some implementations, SNCs 512 can be formed by a series of fabricating processes including thin film deposition processes (e.g., CVD, PVD, ALD, etc.) and patterning processes (e.g., photoetching, dry etching, wet etching, cleaning, chemical mechanical polishing (CMP), etc.)

As shown in FIG. 4, method 400 begins at operation 402, where an insulating wall 520 is extended along the z-direction and the x-direction, as shown in FIG. 5B. In some implementations, a bottom dielectric layer 516 is formed on the SNCs 512. The material of bottom dielectric layer 516 differs from that of insulating wall 520, allowing bottom dielectric layer 516 to serve as an etch stop layer during the formation of insulating wall 520. It helps to prevent issues such as over-etching and other process risks, thereby protecting the SNCs 512 from damage.

Thereafter, an insulating material is deposited on bottom dielectric layer 516 to form an insulating layer 518. The thickness of insulating layer 518 is approximately equal to the height of vertical transistors 530. Two adjacent insulating layer 518 are separated by a trench 519 extending along the x-direction, as shown in FIG. 5C. The material of insulating layer 518 is different from that of the bottom dielectric layer 516, providing the two layers with distinct etching selectivity. This difference ensures that the bottom dielectric layer 516 remains unaffected by the etching process. In some implementations, bottom dielectric layer 516 includes silicon nitride, while insulating layer 518 consists of silicon oxide. Hydrofluoric acid (HF) solution can effectively etch silicon oxide without affecting silicon nitride. HF selectively dissolves silicon oxide, while silicon nitride exhibits strong chemical stability against HF, remaining unetched. In other implementations, bottom dielectric layer 516 may include silicon oxide, and insulating layer 518 may consist of silicon nitride. Phosphoric acid (H₃PO₄) can selectively etch silicon nitride without impacting silicon oxide. Phosphoric acid has good solubility for silicon nitride, whereas its etching rate for silicon oxide is very low. As shown in FIG. 5C, insulating wall 520 is formed by patterning insulating layer 518.

As shown in FIGS. 4 and 5D, method 400 begins at operations 404 and 406, where a first gate electrode layer 521 and a second gate electrode layer 523 are formed and extend along the z-direction and the x-direction. First gate electrode layer 521 and second gate electrode layer 523 belong to two adjacent vertical transistors 530 correspondingly and are located on two sides of insulating wall 520, respectively. In some implementations, a conductive layer is formed covering the insulating wall 520 and then patterned to form gate electrode layers 521 and 523. In some implementations, gate electrode layers 521 and 523 can be formed by a series of fabricating processes, including thin film deposition processes (e.g., CVD, PVD, ALD, etc.) and patterning processes (e.g., photoetching, dry etching, wet etching, cleaning, chemical mechanical polishing (CMP), etc.)

In some implementations, first gate electrode layer 521 and second gate electrode layer 523 include conductive materials including, but not limited to, W, Co, Cu, Al, TiN, TaN, polysilicon, silicide, or any combination thereof. In some implementations, first gate electrode layer 521 includes multiple conductive layers, such as a two-layer structure including TiN/TaN, TaN/Al, TiN/Al, or W/Cu, or a three-layer structure including TiN/TaN/Al or Mo/TiN/Al. In some implementations, first gate electrode layer 521 at least includes a first layer and a second layer coupled to the first layer in the y-direction. The first layer is connected to insulating wall 520, and the second layer is coupled to gate dielectric layer 524. As shown in FIG. 5D, the first layer includes a first sub-layer extending along the z-direction and a second sub-layer connected to an end of the first sub-layer and extending along the y-direction. The second sub-layer of the first layer is located between the first sub-layer of first gate electrode layer 521 and semiconductor layer 526. In some implementations, both the first and second layers have an L-shaped cross-section in the y-z plane. That is, first gate electrode layer 521 includes a first sub-layer extending along the z-direction and a second sub-layer connected to an end of the first sub-layer and extending along the y-direction. The second sub-layer of first gate electrode layer 521 is located between the first sub-layer of first gate electrode layer 521 and semiconductor layer 526. In some implementations, second gate electrode layer 523 may have a similar structure to first gate electrode layer 523 and will not repeat herein.

In some implementations, the heights of gate electrode layers 521 and 523 may be smaller than or equal to the height of insulating layer 518. In some implementations, gate electrode layers 521 and 523 include conductive materials including, but not limited to, W, Co, Cu, Al, TiN, TaN, polysilicon, silicide, or any combination thereof. In some implementations, gate electrode layers 521 and 523 include multiple conductive layers, such as a W layer over a TiN layer. In some implementations, bottom dielectric layer 516 is then patterned to expose SNCs 512 using insulating wall 520 and gate electrode layers 521 and 523 coupled with insulating wall 520 as a hard mask, as shown in FIG. 5D.

As shown in FIGS. 4 and 5E, method 400 begins at operation 408, in which a gate dielectric layer 524 is formed to cover first gate electrode layer 521 and second gate electrode layer 523. Each insulating wall 520 and gate electrode layers 521 and 523 coupled with insulating wall 520 are covered by gate dielectric layer 524. In one example, the gate structure may be a “gate oxide/gate poly” gate in which gate dielectric layer 324 includes silicon oxide and gate electrode layer includes doped polysilicon. In another example, the gate structure may be a high-k metal gate (HKMG) in which gate dielectric layer 524 includes a high-k dielectric and the gate electrode layer includes a metal.

As shown in FIGS. 4 and 5F, method 400 proceeds to operation 410, in which a semiconductor layer 526 is formed to cover gate dielectric layer 524. In some implementations, an intermediate semiconductor layer is formed covering gate dielectric layer 524 by a series of fabricating processes including thin film deposition processes (e.g., CVD, PVD, ALD, etc.) Then the intermediate semiconductor layer is patterned to form a plurality of trenches through a series of patterning processes (e.g., photoetching, dry etching, wet etching, cleaning, chemical mechanical polishing (CMP), etc.) The trenches extend along the y-direction to separate and insulate two rows of vertical transistors in the x-direction.

As shown in FIG. 5F, semiconductor layer 526 includes a first portion covering a first side of insulating wall 520 and a second portion covering a second side of insulating wall 520. As being covered by semiconductor layer 526, first gate electrode layer 521 and second gate electrode layer 523 are disposed between the first portion and the second portion of semiconductor layer 526. In some implementations, a top portion of semiconductor layer 526 is removed so that the first portion and the second portion of semiconductor layer 526 are separated from each other. In some implementations, the top portion of semiconductor layer 526 remains so that the first and second portions of semiconductor layer 526 are connected. The top portion of semiconductor layer 526 may be coupled to a common bit line in the subsequent processes.

In some implementations, the first portion of semiconductor layer 526 includes a first end coupled to a first bit line and a second end coupled to capacitor 510. The second portion of semiconductor layer 526 includes a first end coupled to the first bit line, and a second end coupled to capacitor 510. In some implementations, the first end of the first portion of semiconductor layer 526 and the first end of the second portion of semiconductor layer 526 are connected and coupled to the same common bit line. In some implementations, referring to FIG. 5F, a first distance between the first end of the first portion of semiconductor layer 526 and the first end of the second portion of semiconductor layer 526 is smaller than a second distance between the second end of the first portion of semiconductor layer 526 and the second end of the second portion of semiconductor layer 526. In some implementations, the difference between the first distance and the second distance is substantially equal to the sum of the thickness of first gate electrode layer 521 and a thickness of second gate electrode layer 523. In some implementations, the difference between the first distance and the second distance is greater than the sum of the thicknesses of first gate electrode layer 521 and second gate electrode layer 523 as being affected by the fabricating processes.

In some implementations, semiconductor layer 526 is formed to cover gate dielectric layer 524 by series of fabricating processes including thin film deposition processes (e.g., CVD, PVD, ALD, etc.) Semiconductor layer 526 can be one or more of indium gallium zinc oxide (InₓGa_{y}Zn_{z}O), indium gallium silicon oxide (InₓGa_{y}Si_{z}O), indium stannum zinc oxide (InₓSn_{y}Zn_{z}O), indium zinc oxide (InₓZn_{y}O), zinc oxide (ZnₓO), zinc stannum oxide (ZnₓSn_{y}O), zinc oxide nitride (ZnₓO_{y}N), zirconium zinc stannum oxide (ZrₓZn_{y}Sn_{z}O), stannum oxide (SnₓO), hafnium indium zinc oxide (HfₓIn_{y}Zn_{z}O), gallium zinc stannum oxide (GaₓZn_{y}Sn_{z}O), aluminum zinc stannum oxide (AlₓZn_{y}Sn_{z}O), ytterbium gallium zinc oxide (YbₓGa_{y}Zn_{z}O), indium gallium oxide (InₓGa_{y}O), etc. Then, the intermediate semiconductor layer is patterned to form a plurality of trenches through a series of patterning processes (e.g., photoetching, dry etching, wet etching, cleaning, chemical mechanical polishing (CMP), etc.) The trenches extend along the y-direction to separate and insulate two rows of vertical transistors in the x-direction.

In some implementations, as shown in FIG. 5G, an interlayer dielectric layer 532 is formed to cover the gate dielectric layer 524 and semiconductor layer 526 by a series of fabricating processes including thin film deposition processes (e.g., CVD, PVD, ALD, etc.) and patterning processes (e.g., photoetching, dry etching, wet etching, cleaning, chemical mechanical polishing (CMP), etc.) A top surface of semiconductor layer 526 is exposed from interlayer dielectric layer 532 for interconnection. In some implementations, as shown in FIG. 5H, a plurality of bit lines 528 are formed to contact with a row of vertical transistors 530 along the y-direction. Bit lines 528 are insulated with each other by dielectric materials.

The foregoing description of the specific implementations can be readily modified and/or adapted for various applications. Therefore, such adaptations and modifications are intended to be within the meaning and range of equivalents of the disclosed implementations based on the teaching and guidance presented herein.

Any of the above-described implementations should not limit the breadth and scope of the present disclosure but should be defined only by the following claims and their equivalents.

What is claimed is:

1. A semiconductor device, comprising:
an insulating wall extending along a first direction and a second direction perpendicular to the first direction, the insulating wall having a first side and a second side opposite each other in a third direction perpendicular to the first direction and second direction;
a first gate electrode layer and a second gate electrode layer extending along the first direction and coupled to the first side and the second side of the insulating wall, respectively; and
a first semiconductor layer and a second semiconductor layer extending along the first direction and coupled to the first gate electrode layer and the second gate electrode layer respectively; wherein
a first end of the first semiconductor layer and a first end of the second semiconductor layer are connected; and
the first gate electrode layer and the second gate electrode layer are disposed between the first semiconductor layer and the second semiconductor layer in the third direction.

2. The semiconductor device of claim 1, wherein the first semiconductor layer comprises:
a first section extending along the first direction and overlapping with the first gate electrode layer in the first direction;
a second section extending along the first direction and overlapping with the first gate electrode layer in the third direction; and
a third section connected between the first section and the second section and extending at least along a fourth direction different from the first and second directions.

3. The semiconductor device of claim 2, wherein
a length of the second section in the first direction is equal to or greater than a length of the first gate electrode layer in the first direction.

4. The semiconductor device of claim 2, wherein the second semiconductor layer further comprises:
a fourth section extending along the first direction and overlapping with the second gate electrode layer in the first direction;
a fifth section extending along the first direction and overlapping with the second gate electrode layer in the third direction; and
a sixth section connected between the fourth section and the fifth section and extending at least along a fourth direction different from the first and second directions.

5. The semiconductor device of claim 4, wherein
a length of the fifth section in the first direction is equal to or greater than a length of the second gate electrode layer in the first direction.

6. The semiconductor device of claim 4, wherein the first semiconductor layer further comprises:
a seventh section in contact with an end of the second section away from the first section and extending along the third direction; wherein
the seventh section extends away from the first gate electrode layer.

7. The semiconductor device of claim 6, wherein the second semiconductor layer further comprises:
an eighth section in contact with an end of the fifth section away from the first section and extending along the third direction; wherein
the eighth section extends away from the second gate electrode layer.

8. The semiconductor device of claim 4, wherein the first semiconductor layer further comprises:
a ninth section in contact with an end of the first section away from the second section and extending toward the second semiconductor layer along the third direction; wherein
the ninth section is in contact with the second semiconductor layer.

9. The semiconductor device of claim 8, wherein the second semiconductor layer further comprises:
a tenth section in contact with an end of the fourth section away from the fifth section and extending toward the first semiconductor layer along the third direction; wherein
the tenth section is in contact with the first semiconductor layer.

10. The semiconductor device of claim 9, wherein the ninth section and the tenth section are in contact with a bit line.

11. The semiconductor device of claim 1, wherein
a first distance between a first end of the first semiconductor layer and a first end of the second semiconductor layer is smaller than a second distance between a second end of the first semiconductor layer and a second end of the second semiconductor layer;
the first end of the first semiconductor layer is coupled to a first bit line;
the first end of the second semiconductor layer is coupled to the first bit line;
the second end of the first semiconductor layer is coupled to a first storage unit; and
the second end of the second semiconductor layer is coupled to a second storage unit.

12. The semiconductor device of claim 1, wherein
the first gate electrode layer comprises a first sub-layer extending along the first direction and a second sub-layer connected to an end of the first sub-layer and extending along the third direction; or
the second gate electrode layer comprises a third sub-layer extending along the first direction and a fourth sub-layer connected to an end of the third sub-layer and extending along the third direction.

13. The semiconductor device of claim 12, wherein
the second sub-layer of the first gate electrode layer is located between the first sub-layer of the first gate electrode layer and the first semiconductor layer; or
the fourth sub-layer of the second gate electrode layer is located between the third sub-layer of the second gate electrode layer and the second semiconductor layer.

14. A semiconductor device, comprising:
an insulating wall extending along a first direction and a second direction perpendicular to the first direction, the insulating wall having a first side and a second side opposite each other in a third direction perpendicular to the first direction and second direction;
a first gate electrode layer and a second gate electrode layer extending along the first direction and coupled to the first side and the second side of the insulating wall, respectively; and
a first semiconductor layer and a second semiconductor layer extending along the first direction and coupled to the first gate electrode layer and the second gate electrode layer respectively; wherein
a first distance between a first end of the first semiconductor layer and a first end of the second semiconductor layer is smaller than a second distance between a second end of the first semiconductor layer and a second end of the second semiconductor layer;
the first end of the first semiconductor layer is coupled to a first bit line;
the first end of the second semiconductor layer is coupled to the first bit line;
the second end of the first semiconductor layer is coupled to a first storage unit; and
the second end of the second semiconductor layer is coupled to a second storage unit.

15. A method of fabricating a semiconductor device, comprising:
forming an insulating wall extending along a first direction and a second direction perpendicular to the first direction, the insulating wall having a first side and a second side opposite to each other in a third direction perpendicular to the first direction and second direction;
forming a first gate electrode layer and a second gate electrode layer extending along the first direction and coupled to the first side and the second side of the insulating wall respectively; and
forming a first semiconductor layer and a second semiconductor layer extending along the first direction and coupled to the first gate electrode layer and the second gate electrode layer respectively; wherein
the first gate electrode layer and the second gate electrode layer are disposed between the first semiconductor layer and the second semiconductor layer in the third direction.

16. The method of claim 15, further comprising:
forming a bottom dielectric layer under the insulating wall and extending along the second direction and the third direction; wherein
a material of the bottom dielectric layer is different from a material of the insulating wall.

17. The method of claim 16, wherein forming the first gate electrode layer and the second gate electrode layer comprises:
forming a conductive layer covering the insulating wall; and
patterning the conductive layer to form the first gate electrode layer coupled to the first side of the insulating wall in the third direction and the second gate electrode layer coupled to the second side of the insulating wall in the third direction.

18. The method of claim 17, wherein forming the first gate electrode layer and the second gate electrode layer further comprises:
patterning the bottom dielectric layer to remove part of the bottom dielectric layer that exposed from the first gate electrode layer, the second gate electrode layer, and the insulating wall.

19. The method of claim 18, wherein forming the first semiconductor layer and the second semiconductor layer further comprises:
forming a gate dielectric layer covering the first gate electrode layer and the second gate electrode layer in the third direction and covering an end of the insulating wall in the first direction;
forming an intermediate semiconductor layer covering the gate dielectric layer; and
patterning the intermediate semiconductor layer to form the first semiconductor layer and the second semiconductor layer.

20. The method of claim 19, wherein
a first distance between a first end of the first semiconductor layer and a first end of the second semiconductor layer is smaller than a second distance between a second end of the first semiconductor layer and a second end of the second semiconductor layer;
the first end of the first semiconductor layer is coupled to a first bit line;
the first end of the second semiconductor layer is coupled to the first bit line;
the second end of the first semiconductor layer is coupled to a first storage unit; and
the second end of the second semiconductor layer is coupled to a second storage unit.
